(19) United States
(12) Patent Application Publication
(10) Pub. No.: US 2024/0147695 A1
(43) Pub. Date: May 2, 2024

(54) SEMICONDUCTOR MEMORY DEVICES

(71) Applicant: Samsung Electronics Co., Ltd., Suwon-si (KR)

(72) Inventors: Jaecheon YONG, Suwon-si (KR); Daehong KO, Goyang-si (KR)

(73) Assignees: Samsung Electronics Co., Ltd., Suwon-si (KR); INDUSTRY-ACADEMIC COOPERATION FOUNDATION, YONSEI UNIVERSITY, Seoul (KR)

(21) Appl. No.: 18/485,558

(22) Filed: Oct. 12, 2023

(30) Foreign Application Priority Data
Oct. 27, 2022 (KR) 10-2022-0140510

(51) Int. Cl. H10B 12/00

(52) U.S. Cl. CPC H10B 12/30; H10B 12/03; H10B 12/05

(57) ABSTRACT

A semiconductor memory device including a semiconductor layer including a source area, a channel area, and a drain area arranged in a first horizontal direction on a substrate, a cell capacitor extending in the first horizontal direction on the substrate and including a lower electrode layer, a capacitor dielectric film, and an upper electrode layer connected to the source area, a bit line extending in a vertical direction on the substrate and connected to the drain area, and a gate structure covering the channel area, and the gate structure including a gate dielectric film on the channel area and a gate electrode film on the gate dielectric film, wherein in the vertical direction, a first thickness of an end of the channel area facing the source area is greater than a second thickness of another end of the channel area facing the drain area may be provided.

### CROSS-REFERENCE TO RELATED APPLICATION

This application is based on and claims priority under 35 U.S.C. § 119 to Korean Patent Application No. 10-2022-0140510, filed on Oct. 27, 2022, in the Korean Intellectual Property Office, the disclosure of which is incorporated by reference herein in its entirety.

### BACKGROUND

The inventive concepts relate to semiconductor memory devices, and/or more particularly, to three-dimensional semiconductor memory devices.

According to the requirements for miniaturization, multi-functionality, and high performance of electronic products, high-capacity semiconductor memory devices have been required along with increased integration to provide high-capacity semiconductor memory devices. As the integration of two-dimensional semiconductor memory devices in the related art is mainly determined based on an area occupied by a unit memory cell, the integration of such two-dimensional semiconductor memory devices is increasing but still limited. Therefore, three-dimensional semiconductor memory devices for increasing a memory capacity by stacking a plurality of memory cells in a vertical direction on a substrate have been proposed.

### SUMMARY

Some example embodiments of the inventive concepts provide three-dimensional semiconductor memory devices with improved integrity.

According to an aspect of the inventive concepts, a semiconductor memory device includes a semiconductor layer including a source area, a channel area, and a drain area arranged in a first horizontal direction on a substrate, a cell capacitor extending in the first horizontal direction on the substrate and including a lower electrode layer, a capacitor dielectric film, and an upper electrode layer connected to the source area, a bit line extending in a vertical direction on the substrate and connected to the drain area, and a gate structure covering the channel area, and the gate structure including a gate dielectric film on the channel area and a gate electrode film on the gate dielectric film, wherein in the vertical direction, a first thickness of an end of the channel area facing the source area is greater than a second thickness of another end of the channel area facing the drain area.

According to another aspect of the inventive concepts, a semiconductor memory device includes a plurality of semiconductor layers each including a source area, a channel area, and a drain area arranged in a first horizontal direction on a substrate, the plurality of semiconductor layers being apart from one another in a second horizontal direction orthogonal to the first horizontal direction and in a vertical direction, the plurality of semiconductor layers arranged in columns and rows, a plurality of cell capacitors extending in the first horizontal direction from the plurality of semiconductor layers, the plurality of cell capacitors including a plurality of lower electrode layers connected to source areas of the plurality of semiconductor layers, a capacitor electrode film covering the plurality of lower electrode layers, and an upper electrode film covering the capacitor electrode film, a plurality of bit lines extending in the vertical direction on the substrate the plurality of bit lines arranged apart from one another in the second horizontal direction, the plurality of bit lines each connected to the drain area of a corresponding one of the plurality of semiconductor layers, wherein a thickness of the channel area in the vertical direction decreases from the source area toward the drain area.

According to another aspect of the inventive concepts, a semiconductor memory device includes a plurality of semiconductor layers each including a source area, a channel area, and a drain area arranged in a first horizontal direction on a substrate, the plurality of semiconductor layers being apart from one another in a second horizontal direction orthogonal to the first horizontal direction and in a vertical direction, the plurality of semiconductor layers arranged in columns and rows, a plurality of cell capacitors extending in the first horizontal direction from the plurality of semiconductor layers, the plurality of cell capacitors including a plurality of lower electrode layers connected to source areas of the plurality of semiconductor layers, a capacitor dielectric film covering the plurality of lower electrode layer, and an upper electrode film covering the capacitor dielectric film, a plurality of bit lines extending in the vertical direction on the substrate, the plurality of bit lines connected to the drain area of each of a group of semiconductor layers, which are arranged apart from one another in the vertical direction from among the plurality of semiconductor layers, the plurality of bit lines arranged apart from one another in the second horizontal direction, a plurality of gate structures extending in the second horizontal direction, the plurality of gate structures surrounding the channel area of each of a group of semiconductor layers arranged apart from one another in the second horizontal direction from among the plurality of semiconductor layers, the plurality of gate structures each including a gate dielectric film on the channel area and a gate electrode film on the gate dielectric film, a plurality of word line contacts extending in the vertical direction, the plurality of word line contacts arranged apart from one another in the second horizontal direction, the plurality of word line contacts being apart from the plurality of bit lines in the first horizontal direction, each of the plurality of word line contacts connected to the gate electrode film of a corresponding one of the plurality of gate structures, and an insulating layer covering the plurality of semiconductor layers, the plurality of gate structures, the plurality of cell capacitors, the plurality of bit lines, and the plurality of word line contacts, on the substrate, and filling a space between one of the plurality of bit lines and a corresponding one of the plurality of word line contacts which is adjacent to the one of the plurality of bit lines in the first horizontal direction.

### BRIEF DESCRIPTION OF THE DRAWINGS

Example embodiments of the inventive concepts will be more clearly understood from the following detailed description taken in conjunction with the accompanying drawings in which:

FIGS. 1A to 17B are diagrams showing a process order to describe a method of manufacturing a semiconductor memory device according to an example embodiment of the inventive concepts;

FIGS. 18A to 18D are diagrams of a semiconductor memory device according to an example embodiment of the inventive concepts;

FIGS. 19A to 19B are diagrams of a semiconductor memory device according to an example embodiment of the inventive concepts; and

FIG. 20 is an equivalent circuit diagram of a cell array of a semiconductor memory device according to an example embodiment of the inventive concepts.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

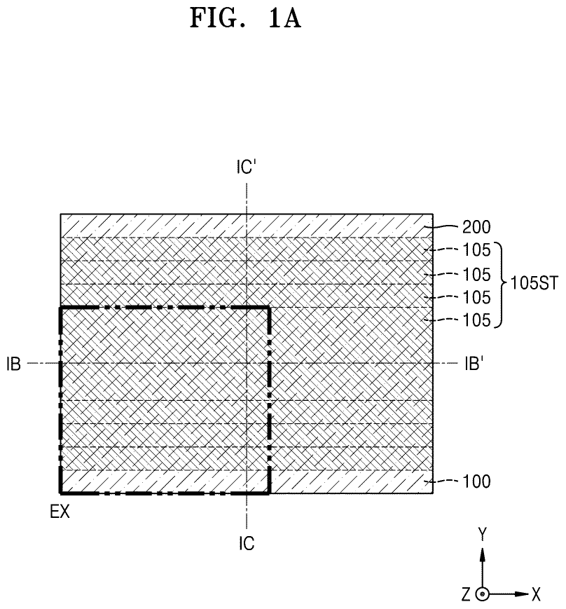

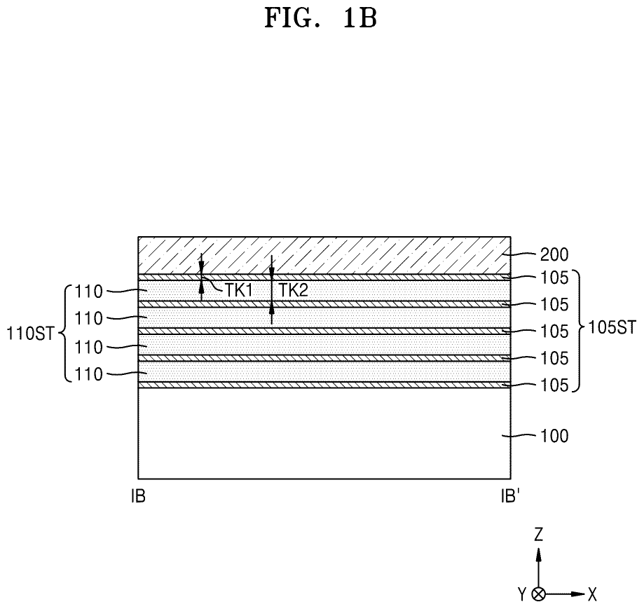

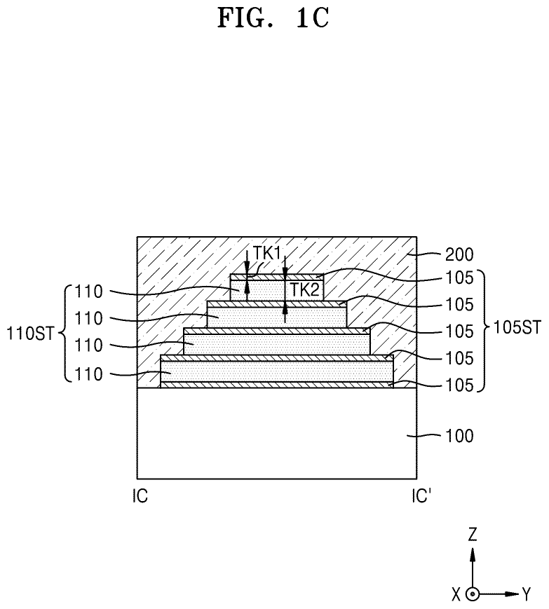

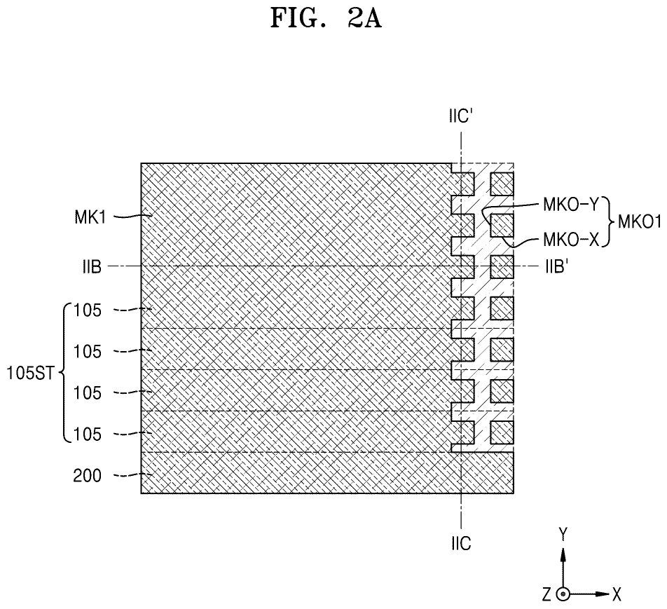

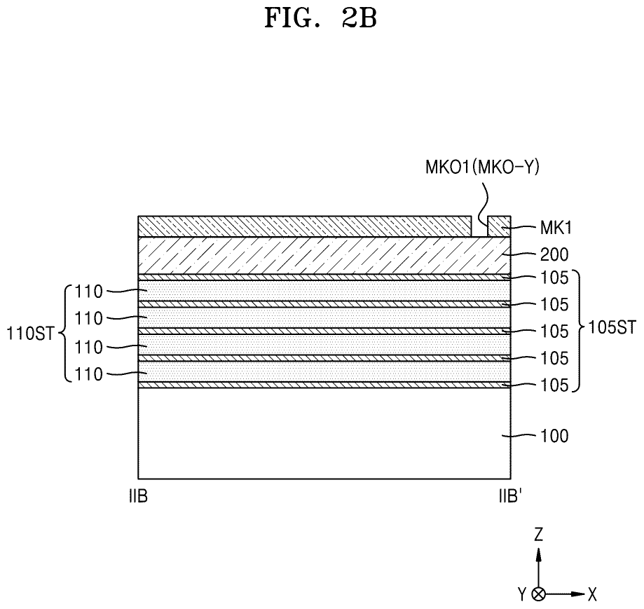

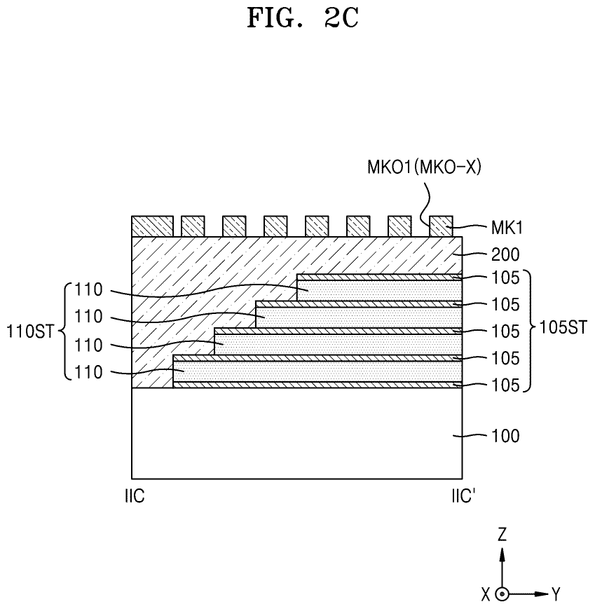

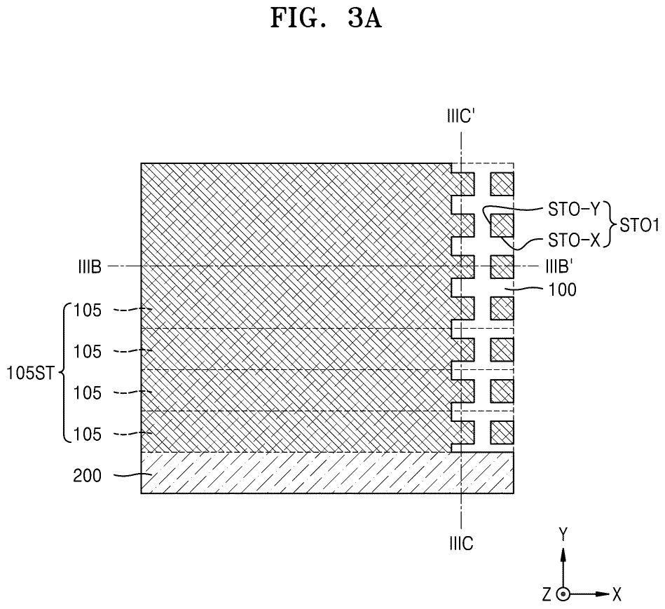

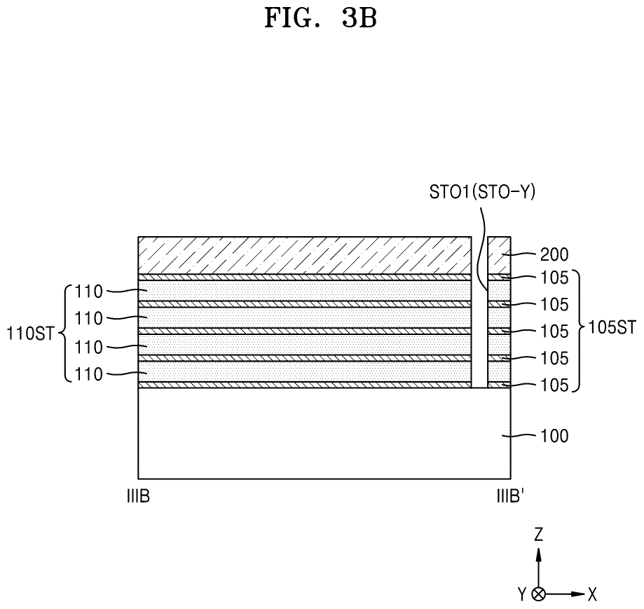

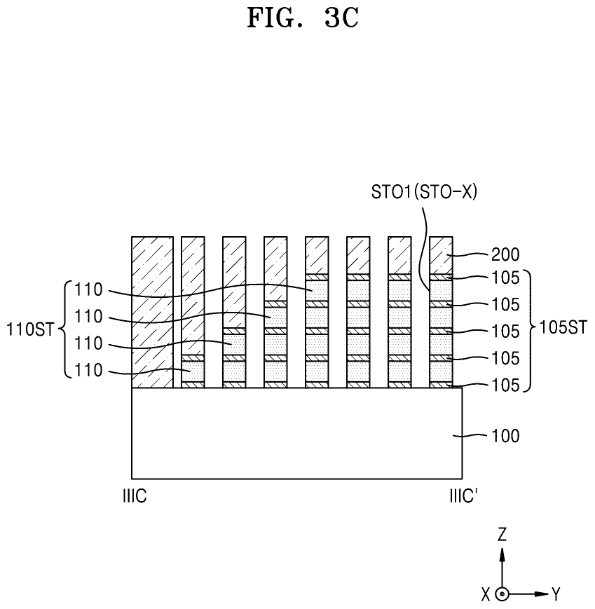

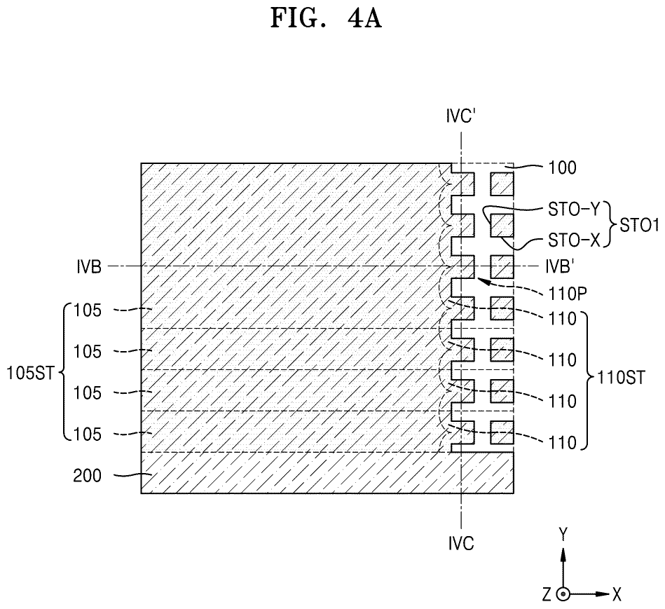

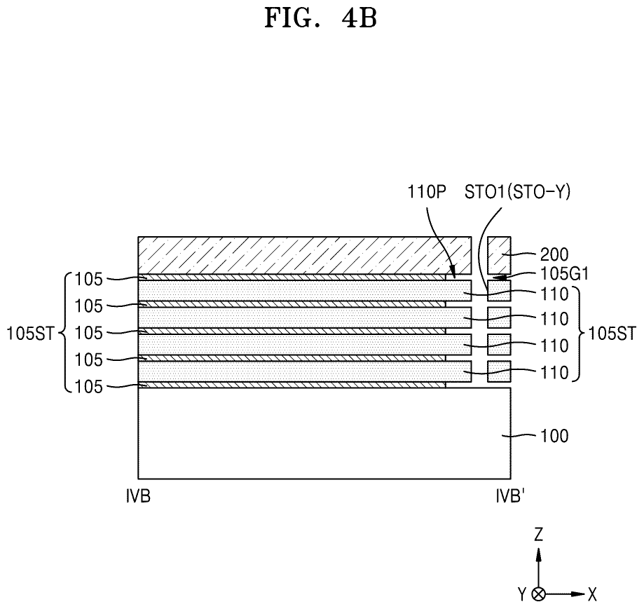

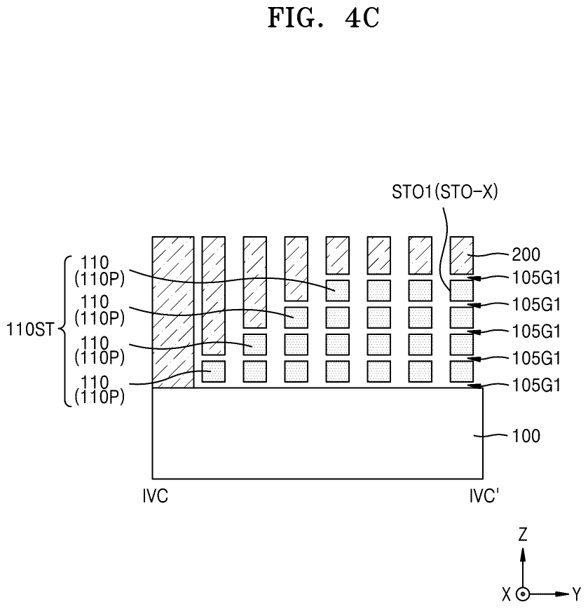

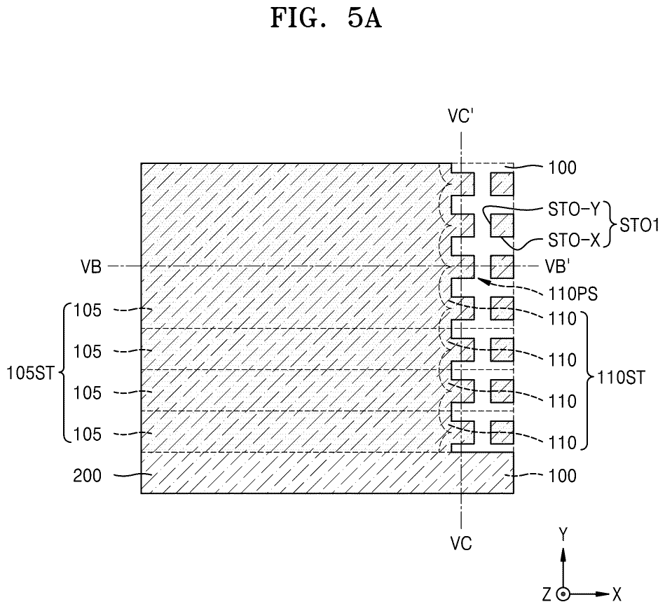

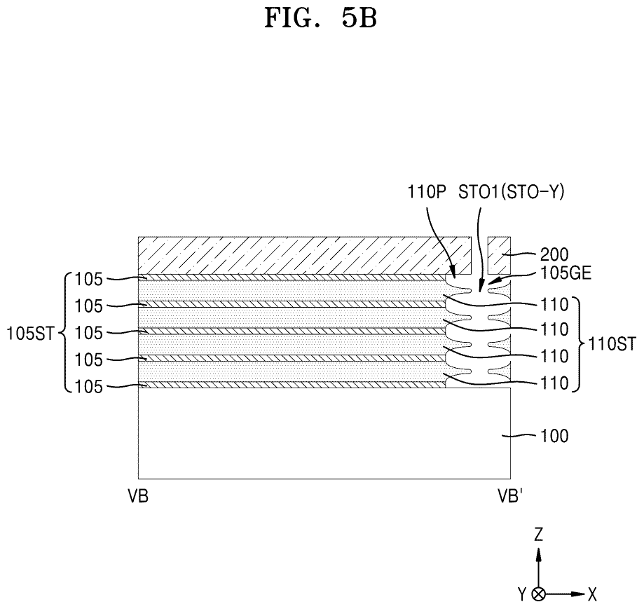

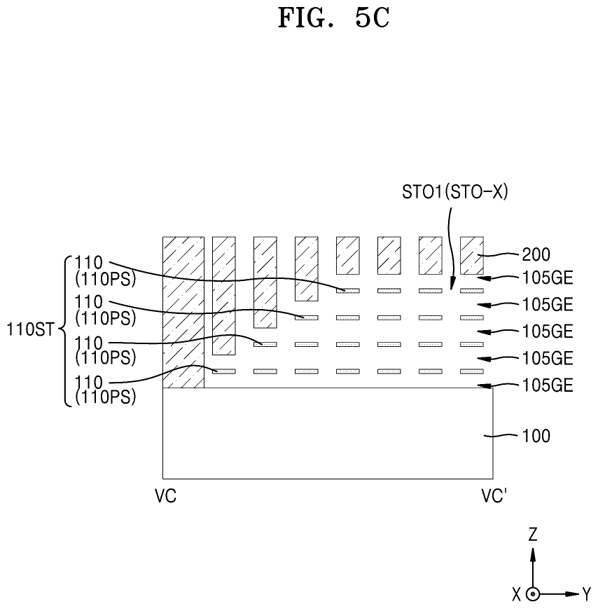

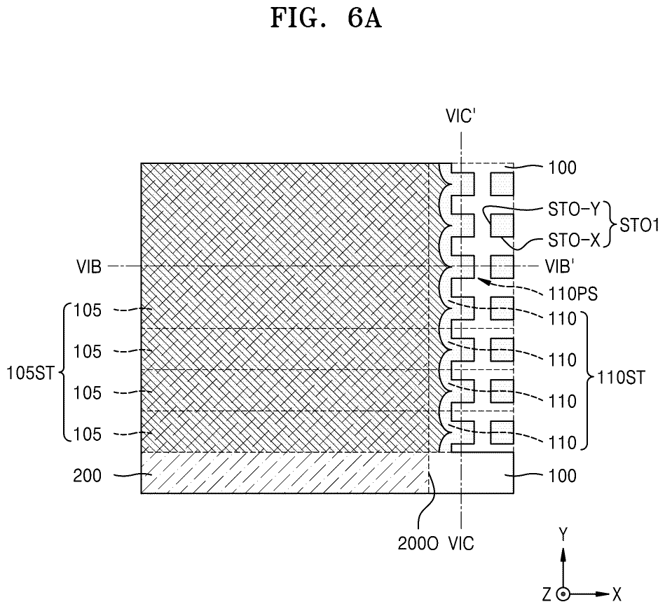

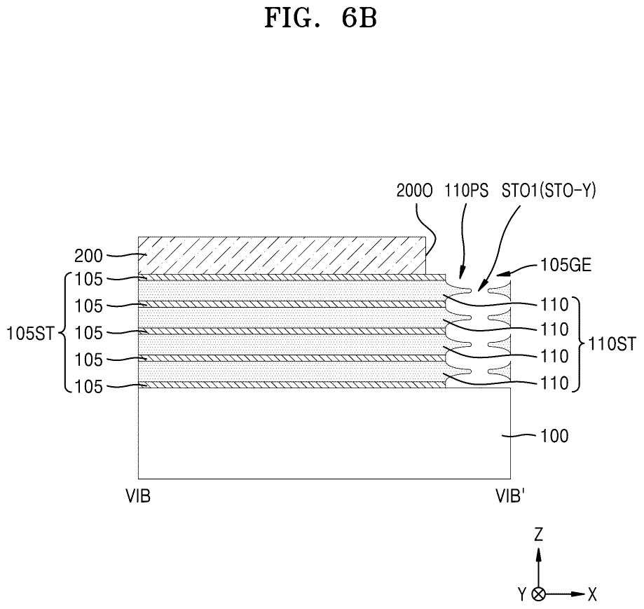

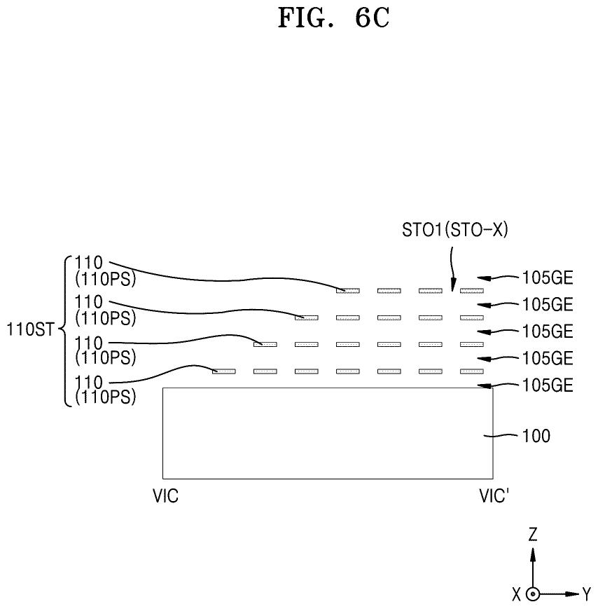

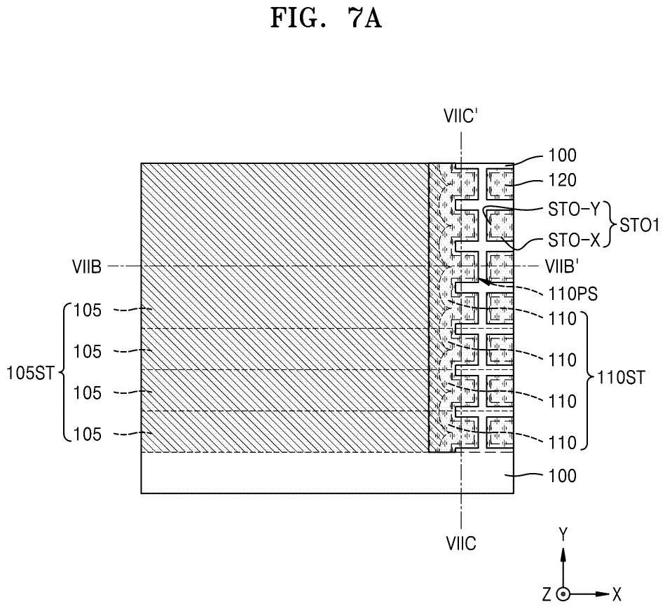

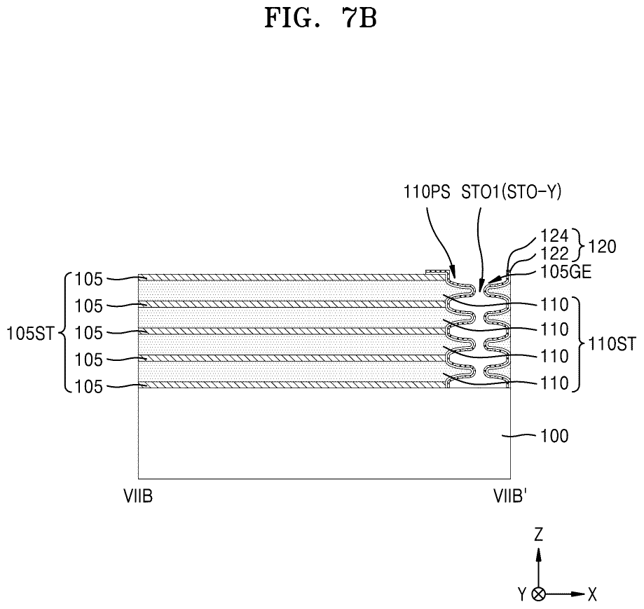

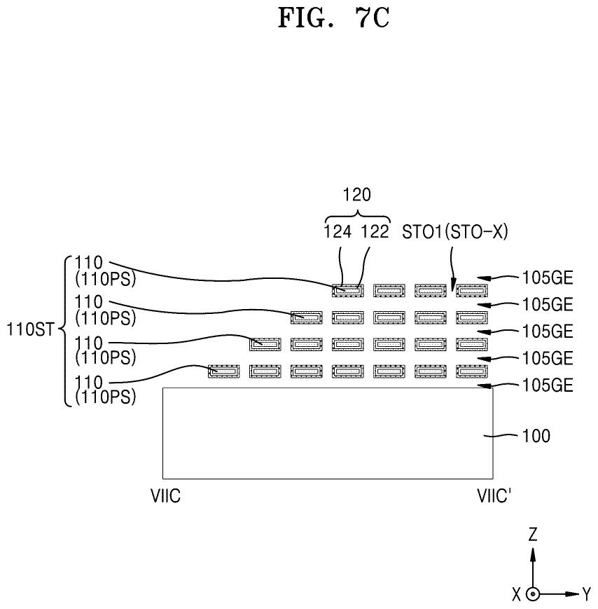

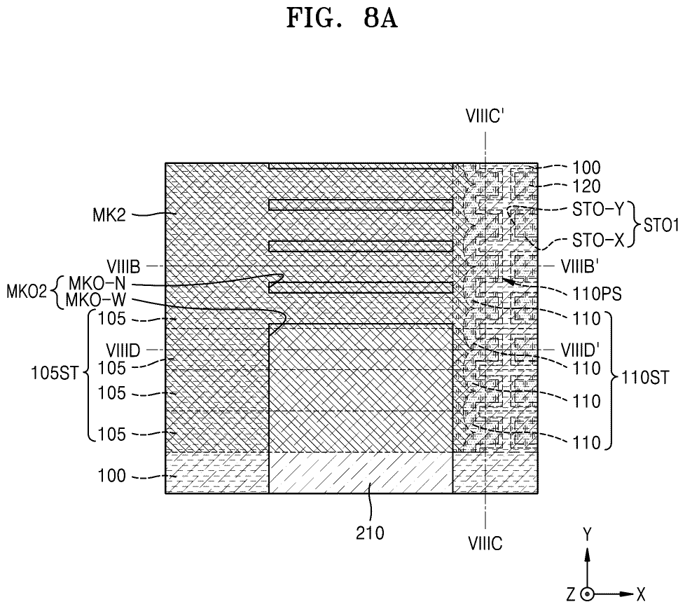

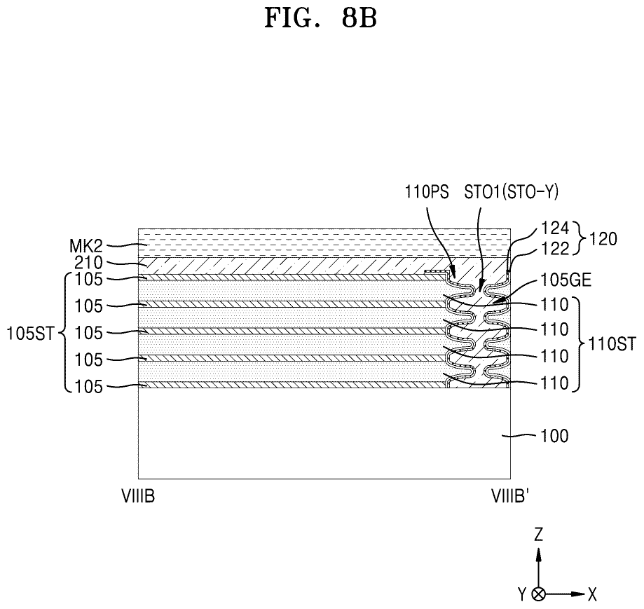

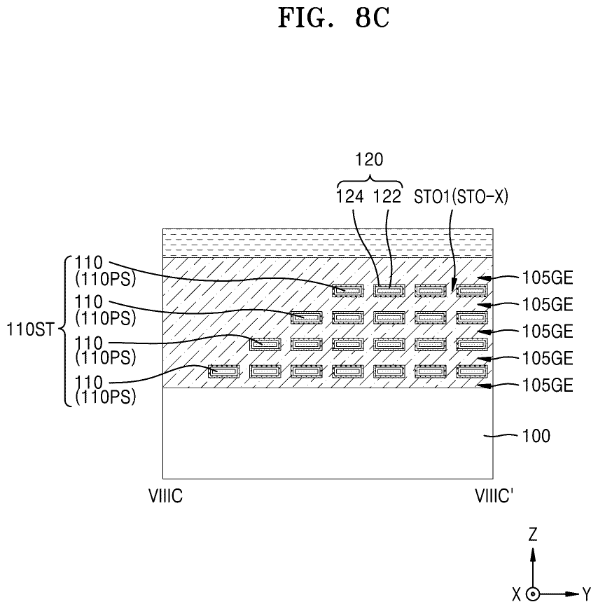

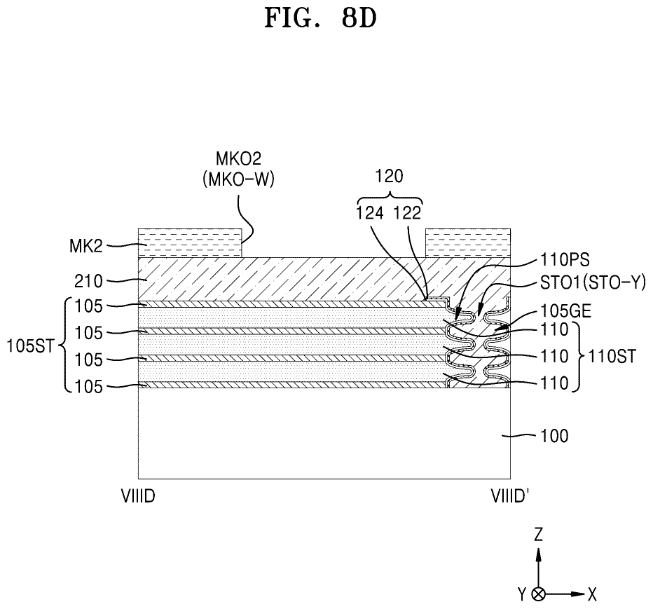

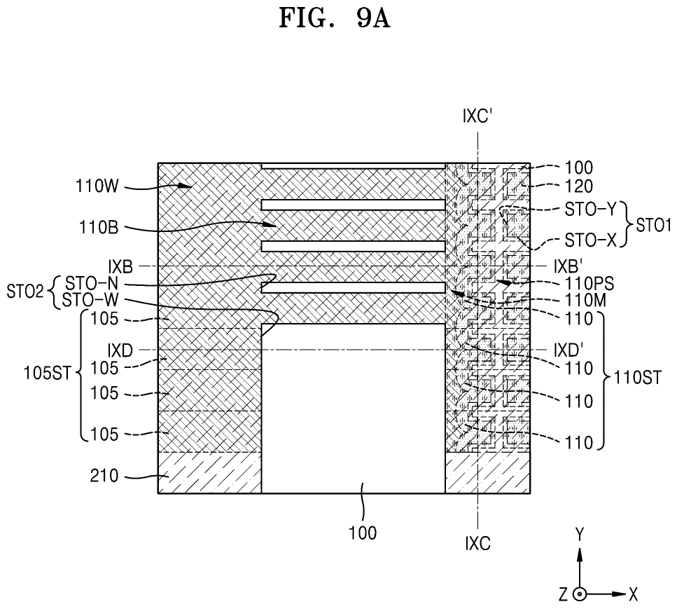

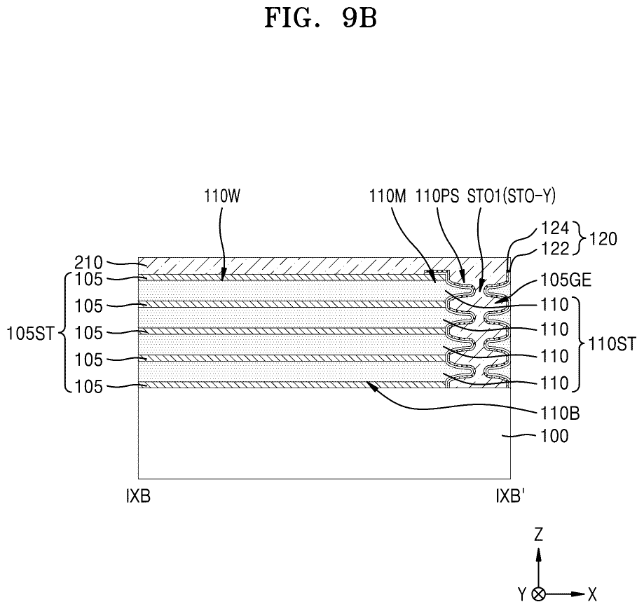

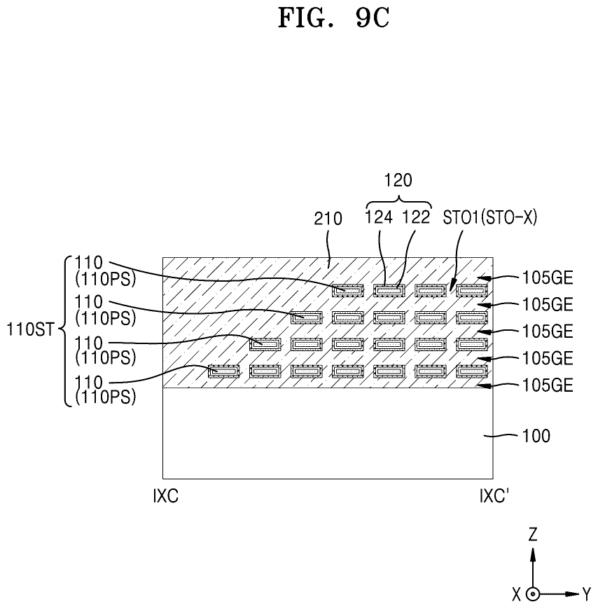

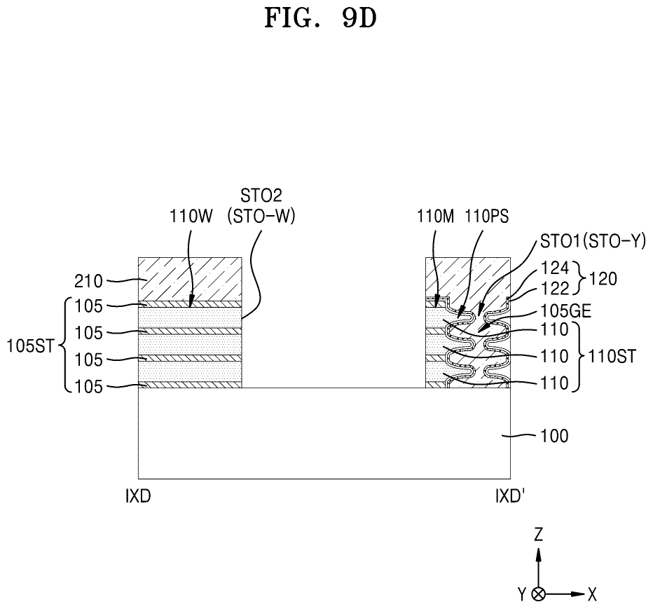

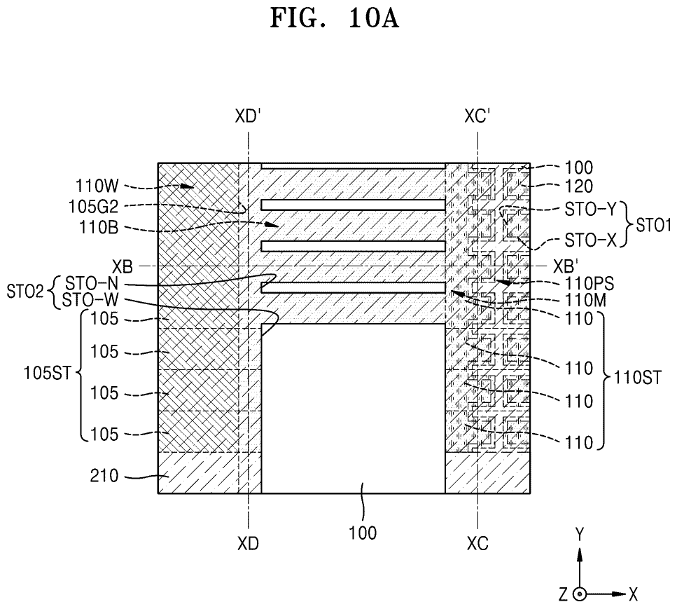

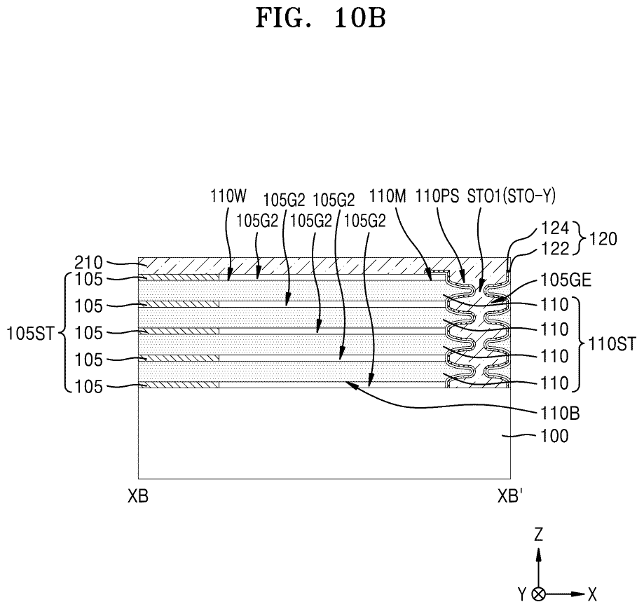

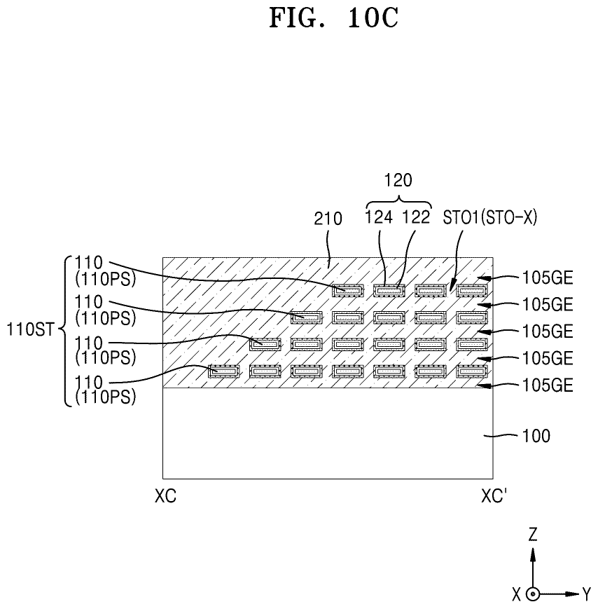

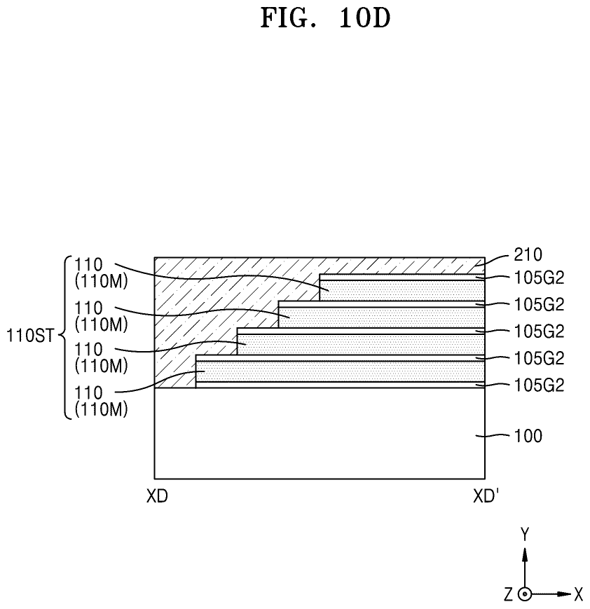

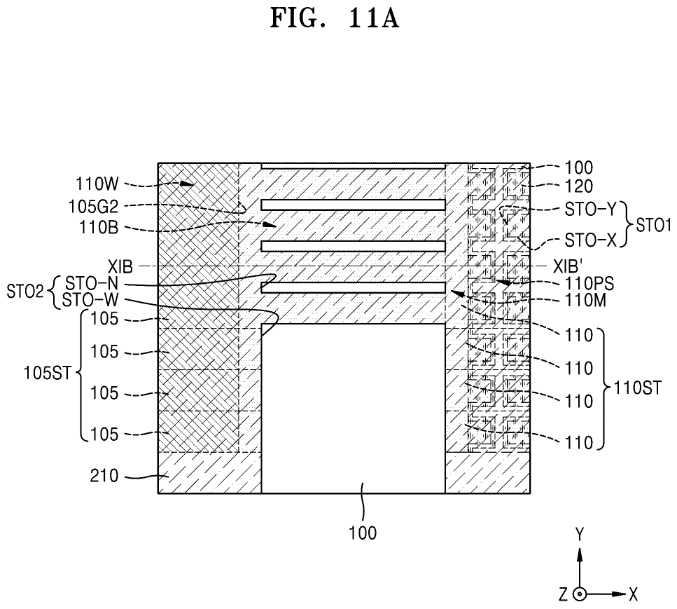

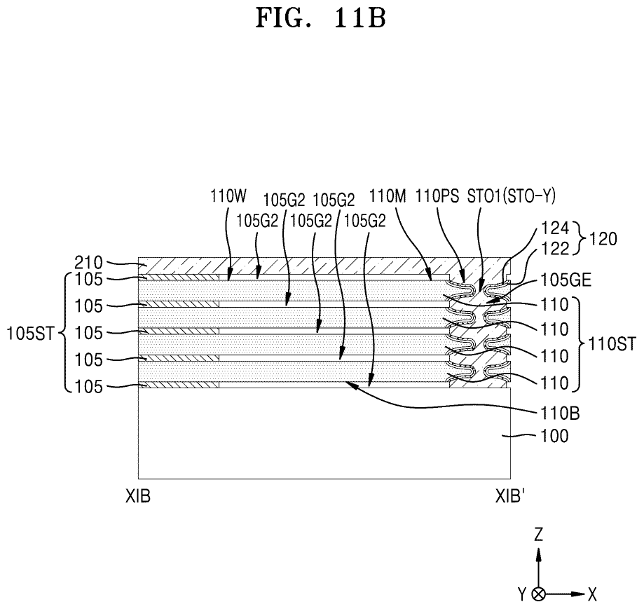

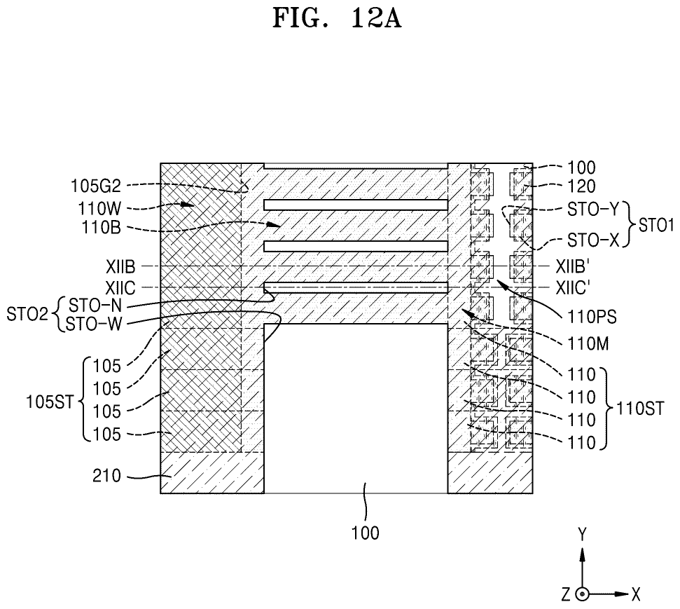

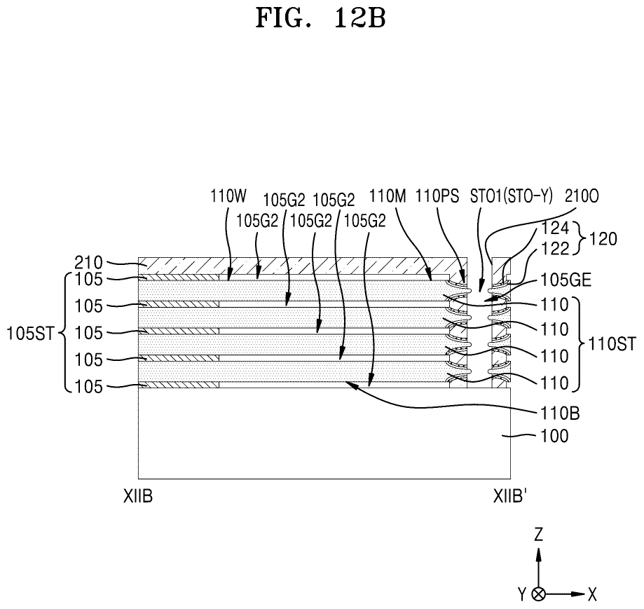

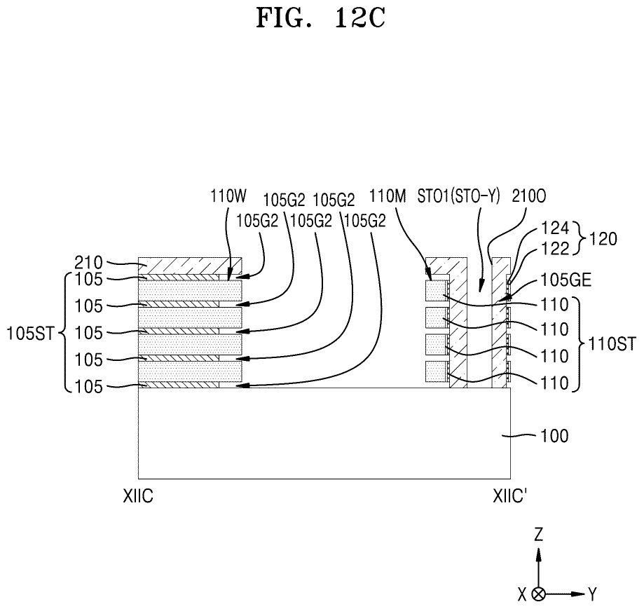

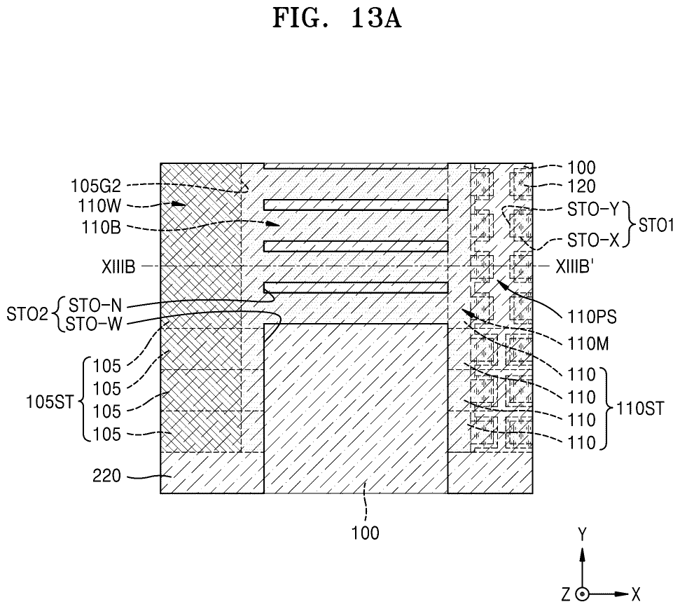

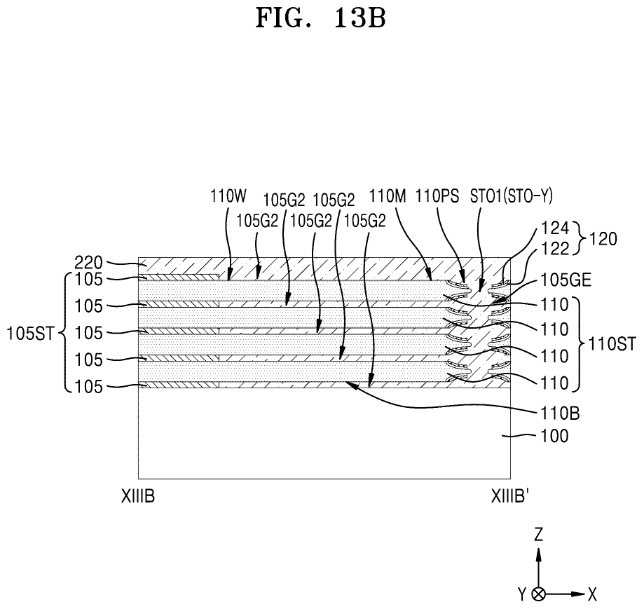

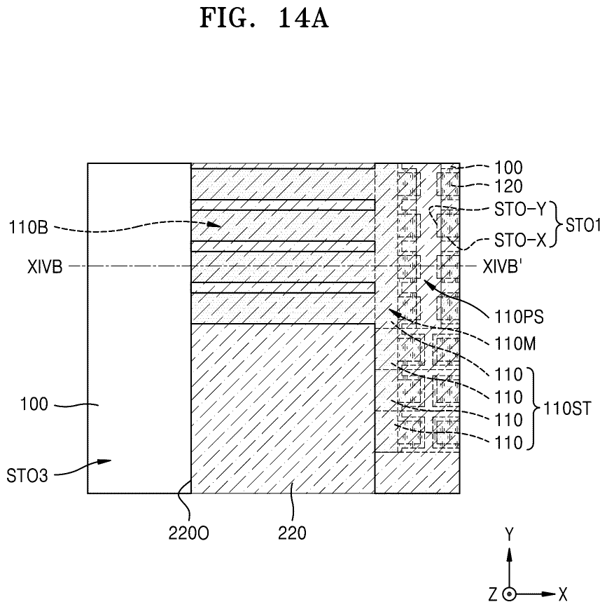

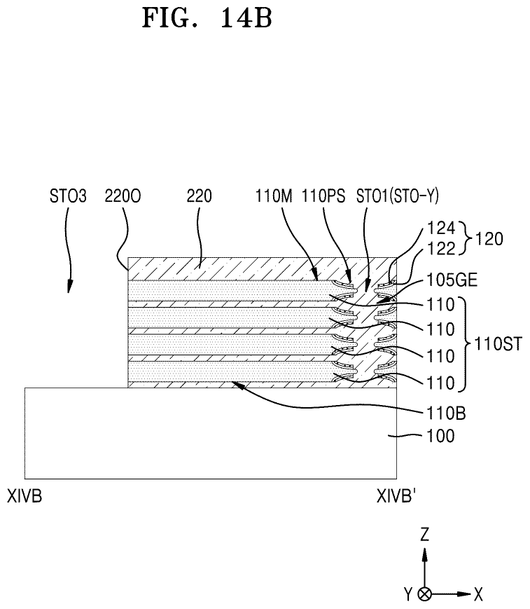

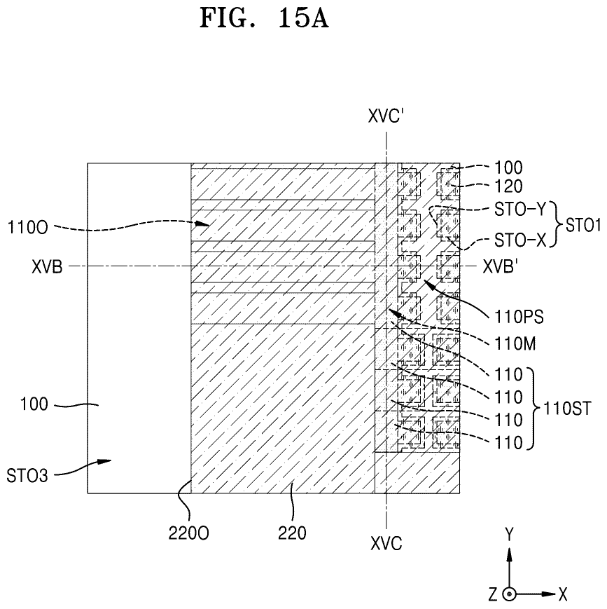

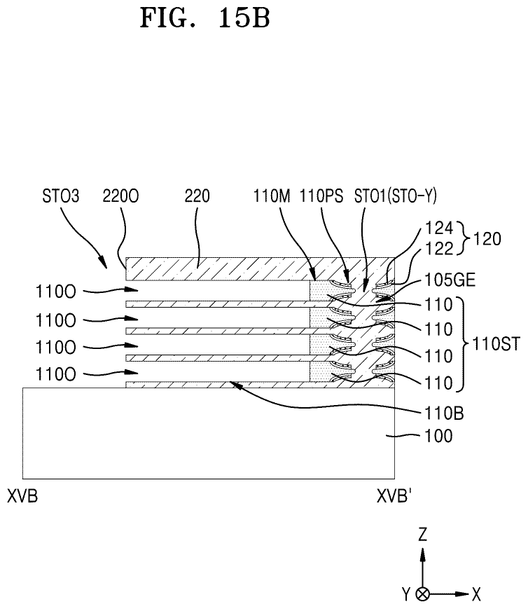

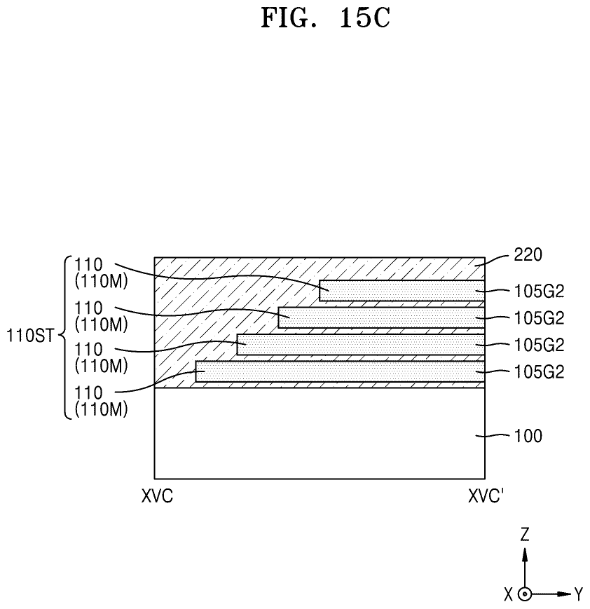

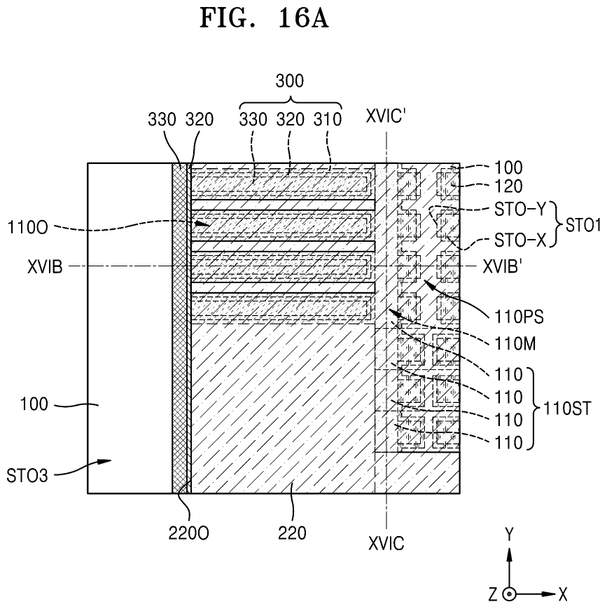

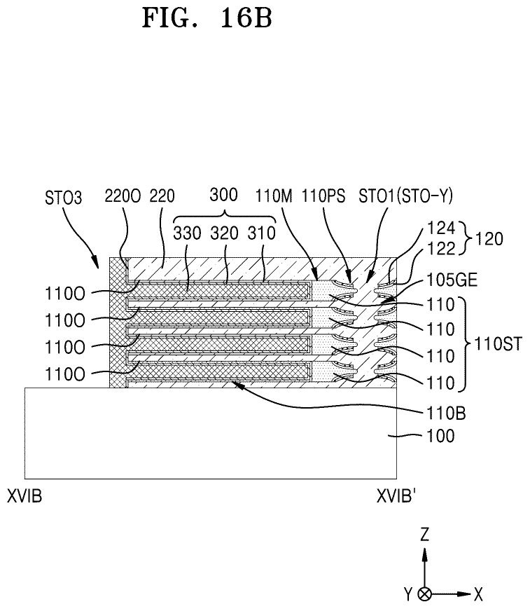

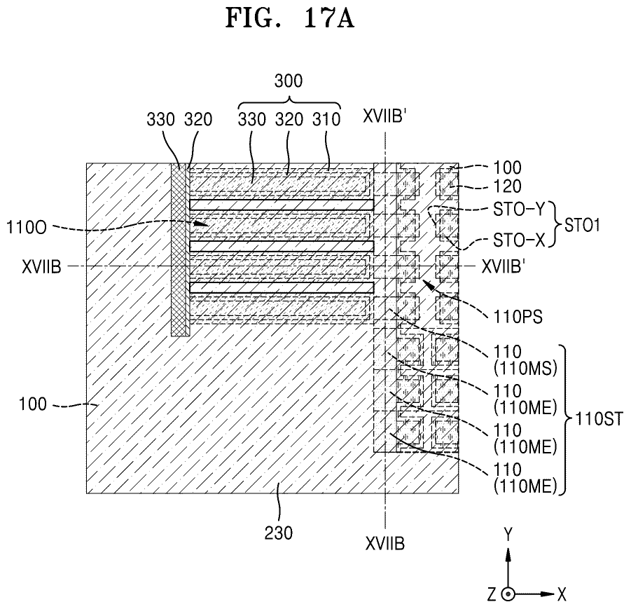

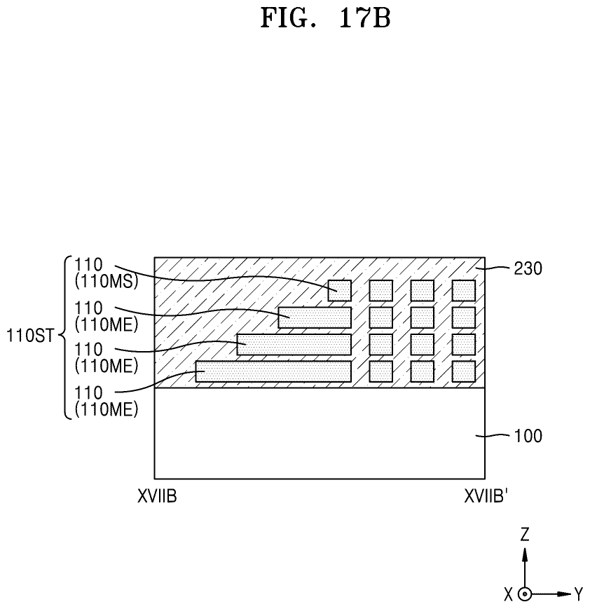

FIGS. 1A to 17B are diagrams showing a process order to describe a method of manufacturing a semiconductor memory device according to an example embodiment of the inventive concepts. More particularly, FIGS. 1A, 2A, 3A, 4A, 5A, 6A, 7A, 8A, 9A, 10A, 11A, 12A, 13A, 14A, 15A, 16A, and 17A each are a top-plan view seen from top; FIGS. 1B, 2B, 3B, 4B, 5B, 6B, 7B, 8B, 9B, 10B, 11B, 12B, 13B, 14B, 15B, 16B, and 17B each are a diagram of a cross-section taken along line IB-IB′ shown in FIG. 1A, line IIB-IIB′ shown in FIG. 2A, line IIIB-IIIB′ shown in FIG. 3A, line IVB-IVB′ shown in FIG. 4A, line VB-VB′ shown in FIG. 5A, line VIB-VIB′ shown in FIG. 6A, line VIIB-VIIB′ shown in FIG. 7A, line VIIIB-VIIIB′ shown in FIG. 8A, line IXB-IXB′ shown in FIG. 9A, line XB-XB′ shown in FIG. 10A, line XIB-XIB′ shown in FIG. 11A, line XIIB-XIIB′ shown in FIG. 12A, line XIIIB-XIIIB′ shown in FIG. 13A, line XIVB-XIVB′ shown in FIG. 14A, line XVB-XVB′ shown in FIG. 15A, line XVIB-XVIB′ shown in FIG. 16A, line XVIIB-XVIIB′ shown in FIG. 17A; FIGS. 1C, 2C, 3C, 4C, 5C, 6C, 7C, 8C, 9C, 10C, 12C, and 15C each are a diagram of a cross-section taken along line IC-IC′ shown in FIG. 1A, line IIC-IIC′ shown in FIG. 2A, line IIIC-IIIC′ shown in FIG. 3A, line IVC-IVC′ shown in FIG. 4A, line VC-VC′ shown in FIG. 5A, line VIC-VIC′ shown in FIG. 6A, line VIIC-VIIC′ shown in FIG. 7A, line VIIIC-VIIIC′ shown in FIG. 8A, line IXC-IXC′ shown in FIG. 9A, line XC-XC′ shown in FIG. 10A, line XIIC-XIIC′ shown in FIG. 12A, and line XVC-XVC′ shown in FIG. 15A; and FIGS. 8D, 9D, and 10D each are a diagram of a cross-section taken along line VIIID-VIIID′ shown in FIG. 8A, line IXD-IXD′ shown in FIG. 9A, and line XD-XD′ shown in FIG. 10A. In addition, FIGS. 2A to 17B are top-plan views and cross-sectional views of portion EX shown in FIG. 1A.

Referring to FIGS. 1A to 1C, a plurality of sacrificial layers 105 and a plurality of semiconductor layers 110 are formed on a substrate 100. The plurality of sacrificial layers 105 and the plurality of semiconductor layers 110 may be alternately stacked on the substrate 100. The plurality of sacrificial layers 105 may be named as a stacked sacrificial structure 105ST, and the plurality of semiconductor layers 110 may be named as a stacked semiconductor structure 110ST. The stacked sacrificial structure 105ST may include the plurality of sacrificial layers 105 arranged apart from one another in a vertical direction (a Z direction) on the substrate 100. The stacked semiconductor structure 110ST may include the plurality of semiconductor layers 110 arranged apart from one another in the vertical direction (the Z direction) on the substrate 100.

The stacked semiconductor structure 110ST may be included in the stacked sacrificial structure 105ST in an interposed manner. For example, each of the plurality of semiconductor layers 110 may be between two sacrificial layers 105 adjacent to each other and apart from each other in the vertical direction (the Z direction). The number of the plurality of sacrificial layers 105 included in the stacked sacrificial structure 105ST may be greater by one than the number of the plurality of semiconductor layers 110 included in the stacked semiconductor structure 110ST. Although FIGS. 1A to 1C illustrate that the stacked sacrificial structure 105ST includes five sacrificial layers 105 and the stacked semiconductor structure 110ST includes four semiconductor layers 110, this is merely an example embodiment, and the inventive concepts may be not limited thereto. For example, the stacked sacrificial structure 105ST may include six or more, or tens to thousands of sacrificial layers 105, and the stacked semiconductor structure 110ST may include five or more, or tens to hundreds of semiconductor layers 110.

The substrate 100 may include, for example, silicon (Si), for example, crystalline Si, polycrystalline Si, or amorphous Si. In some example embodiments, the substrate 100 may include a semiconductor element such as germanium (Ge), or at least one compound semiconductor selected from among silicon germanium (SiGe), silicon carbide (SiC), gallium arsenide (GaAs), indium arsenide (InAs), and indium phosphide (InP). In some example embodiments, the substrate 100 may include a silicon-on-insulator (SOI) substrate or a germanium-on-insulator (GeOI) substrate. For example, the substrate 100 may include a buried oxide (BOX) layer. The substrate 100 may include a conductive area, for example, a well doped with impurities or a structure doped with impurities.

The plurality of sacrificial layers 105 and the plurality of semiconductor layers 110 may each include a semiconductor material. The sacrificial layer 105 may include a semiconductor material having an etching selectivity ratio with respect to the semiconductor layer 110. In some example embodiments, the sacrificial layer 105 may have an etching selectivity ratio with respect to the substrate 100. In some example embodiments, a semiconductor layer 110 may include a material having same or similar etching properties such as those of the substrate 110, or may include a same material as the substrate 100. For example, each of the plurality of sacrificial layers 105 may include SiGe, and each of the plurality of semiconductor layers 110 may include Si.

In some example embodiments, the plurality of sacrificial layers 105 and the plurality of semiconductor layers 110 may each include a monocrystalline semiconductor material. For example, the plurality of sacrificial layers 105 may each include monocrystalline SiGe, and the plurality of semiconductor layers 110 may each include monocrystalline Si.

In some other example embodiments, the plurality of semiconductor layers 110 each may include a two-dimensional (2D) semiconductor material or an oxide semiconductor material. For example, the 2D semiconductor material may include MoS₂, WSe₂, Graphene, Carbon Nano Tube, or combinations thereof. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. For example, each of the plurality of semiconductor layers 110 may include a single layer or multiple layers including the oxide semiconductor material. In some example embodiments, each of the plurality of semiconductor layers 110 may include a material having a bandgap energy greater than a bandgap energy of Si. For example, each of the plurality of semiconductor layers 110 may include a material having a bandgap energy of from about 1.5 eV to about 5.6 eV. For example, each of the plurality of semiconductor layers 110 may include a material that may have optimal channel properties when having a bandgap energy of from about 2.0 eV to about 4.0 eV.

The plurality of sacrificial layers 105 and the plurality of semiconductor layers 110 may be formed through chemical vapor deposition (CVD) process, plasma enhanced CVD (PECVD) process, or atomic layer deposition (ALD) process. In some example embodiments, each of the plurality of sacrificial layers 105 and the plurality of semiconductor layers 110 may be formed in a monocrystalline state using a layer thereunder (e.g., the substrate 100, a sacrificial layer 105, or a semiconductor layer 110) as a seed layer, or may be formed in a monocrystalline state through a thermal treatment process.

The plurality of sacrificial layers 105 may be formed in an approximately same thickness. The plurality of semiconductor layers 110 may be formed in an approximately same thickness. Each of the plurality of sacrificial layers 105 may have a first film thickness TK1, and each of the plurality of semiconductor layers 110 may have a second film thickness TK2. The first film thickness TK1 may have a value smaller than a value of the second film thickness TK2. For example, the second film thickness TK2 may be twice or four times the first film thickness TK1. In some example embodiments, the first film thickness TK1 may be from about 10 nm to about 20 nm, and the second film thickness TK2 may be from about 20 nm to about 50 nm.

The plurality of sacrificial layers 105 and the plurality of semiconductor layers 110 may be formed in an approximately horizontal width (e.g., in a first horizontal width) in a first horizontal direction (an X direction), respectively. The plurality of semiconductor layers 110 may be formed away from the substrate 100 in the vertical direction (the Z direction) in a smaller horizontal width (e.g., in a second horizontal width smaller than the first horizontal width) in a second horizontal direction (the Y direction) orthogonal to the first horizontal direction (the X direction). For example, a semiconductor layer 110 at bottom of the plurality of semiconductor layers 110 may be formed in a greatest horizontal width in the second horizontal direction (the Y direction), a semiconductor layer 110 at top of the plurality of semiconductor layers 110 may be formed in a smallest horizontal width in the second horizontal direction (the Y direction), the plurality of semiconductor layers 110 may move away in the vertical direction (the Z direction) from the substrate 100 and have a horizontal thickness in the second horizontal direction (the Y direction) decreasing at an approximately same ratio. The plurality of semiconductor layers 110 may have a step shape at two ends in the second horizontal direction (the Y direction). For example, the plurality of semiconductor layers 110 may be formed such that gaps (e.g., differences) between horizontal widths in the second horizontal direction (the Y direction) of pairs of two semiconductor layers 110 adjacent to one another in the vertical direction are approximately same.

A horizontal width in the second horizontal direction (the Y direction) of the sacrificial layer 105 covering a top surface of any one semiconductor layer 110 from among the plurality of semiconductor layers 110 may be approximately identical to a horizontal width in the second horizontal direction (the Y direction) of a corresponding one of the semiconductor layer 110 from among the plurality of semiconductor layers 110. A horizontal width in the second horizontal direction (the Y direction) of the sacrificial layer 105 covering a bottom surface of the semiconductor layer 110 at the bottom of the plurality of semiconductor layers 110 may be approximately identical to a horizontal width in the second horizontal direction (the Y direction) of the semiconductor layer 110 at the bottom of the plurality of semiconductor layers 110. That is, from among the plurality of sacrificial layers 105, the sacrificial layer 105 at bottom and the sacrificial layer 105 thereon may have an approximately same horizontal width in the second horizontal direction (the Y direction). From among the plurality of sacrificial layers 105, other sacrificial layers 105 except the sacrificial layer 105 at the bottom may be formed away in the vertical direction (the Z direction) from the substrate 100 and may have a smaller horizontal widths in the second horizontal direction (the Y direction). From among the plurality of sacrificial layers 105, the other sacrificial layers 105 except the sacrificial layer 105 at the bottom may have a step shape at two ends of the other sacrificial layers 105 in the second horizontal direction (the Y direction).

A first insulating layer 200 covering the stacked sacrificial structure 105ST and the stacked semiconductor structure 110ST may be formed on the substrate 100. For example, the first insulating layer 200 may include an oxide. The first insulating layer 200 may be formed on the substrate 100 by forming a first preliminary insulating material layer (not shown) covering the stacked sacrificial structure 105ST and the stacked semiconductor structure 110ST, and then performing a planarization process of removing a portion of top of the first preliminary insulating material layer. For example, the first insulating layer 200 may be formed by performing a CMP process in which a portion of the top of the first preliminary insulating material layer is removed.

A vertical level of an upper surface of the first insulating layer 200 may be higher than a vertical level of an upper surface of the stacked sacrificial structure 105ST (e.g., a vertical level of an upper surface of the sacrificial layer 105 at top of the plurality of sacrificial layers 105). For example, the first insulating layer 200 may be formed to cover upper surfaces of the stacked sacrificial structure 105ST and the stacked semiconductor structure 110ST.

Referring to FIGS. 2A to 2C, a first mask layer MK1 having a first mask opening MKO1 is formed on the first insulating layer 200. The first mask layer MK1 may include a photoresist or a hard-mask material. The first mask opening MKO1 may expose a portion of the first insulating layer 200.

The first mask opening MKO1 may include a plurality of first horizontal mask openings MKO-X and a plurality of second horizontal mask openings MKO-Y communicating each other. The second horizontal mask opening MKO-Y may have a planar shape of a line or bar extending in the second horizontal direction (the Y direction). Each of the plurality of first horizontal mask openings MKO-X may have a planar shape of a line or bar crossing with the second horizontal mask opening MKO-Y and extending in the first horizontal direction (the X direction). The plurality of first horizontal mask openings MKO-X may be apart from one another in the second horizontal direction (the Y direction) and cross with the second horizontal mask openings MKO-Y.

The number of the plurality of first horizontal mask openings MKO-X may be greater than the number of the plurality of semiconductor layers 110. Some of the plurality of first horizontal mask openings MKO-X may each extend in the first horizontal direction (the X direction) along step-shaped risers of the stacked sacrificial structure 105ST and the stacked semiconductor structure 110ST. For example, some of the plurality of first horizontal mask openings MKO-X may overlap in a vertical direction portions of two treads located at different vertical levels of the step shapes of the stacked sacrificial structure 105ST and stacked semiconductor structure 110ST. Others of the plurality of first horizontal mask openings MKO-X may all overlap the upper surface of the semiconductor layer 110 at the top of the plurality of semiconductor layers 110 and the upper surface of the sacrificial layer 105 at the top of the plurality of sacrificial layers 105.

In some example embodiments, the second horizontal mask opening MKO-Y may extend in the second horizontal direction (the Y direction) along centers of the plurality of first horizontal mask openings MKO-X in the first horizontal direction (the X direction).

The second horizontal mask opening MKO-Y may extend in the second horizontal direction (the Y direction) between the stacked sacrificial structure 105ST and the stacked semiconductor structure 110ST. Although FIGS. 2A to 2C illustrate that the first mask layer MK1 has a second horizontal mask opening MKO-Y, this is merely an example, and example embodiments are not limited thereto. For example, the first mask layer MK1 may have the plurality of second horizontal mask openings MKO-Y apart from one another in the first horizontal direction (the X direction) and extending in the second horizontal direction (the Y direction), and may also include the plurality of first horizontal mask openings MKO-X respectively crossing with the plurality of second horizontal mask openings MKO-Y, which are apart from one another in the second horizontal direction (the Y direction) and extend in the first horizontal direction (the X direction).

A horizontal width of the first horizontal mask opening MKO-X in the first horizontal direction (the X direction) may have a value greater than a value of a horizontal width of the second horizontal mask opening MKO-Y in the first horizontal direction (the X direction). For example, the horizontal width of the first horizontal mask opening MKO-X in the first horizontal direction (the X direction) may be about 750 nm, and the horizontal width of the second horizontal mask opening MKO-Y in the first horizontal direction (the X direction) may be about 200 nm.

A horizontal width of the first horizontal mask opening MKO-X in the second horizontal direction (the Y direction) may have a value smaller than the horizontal width of the first horizontal mask opening MKO-X in the first horizontal direction (the X direction). For example, the horizontal width of the first horizontal mask opening MKO-X in the second horizontal direction (the Y direction) may be about 250 nm. In some example embodiments, the horizontal widths of the first horizontal mask opening MKO-X in the second horizontal direction (the Y direction) may have a value greater than a value of the horizontal width of the second horizontal mask opening MKO-Y in the first horizontal direction (the X direction).

In some example embodiments, a distance between the plurality of first horizontal mask opening MKO-X in the second horizontal direction (the Y direction) may be approximately identical to the horizontal width of the first horizontal mask opening MKO-X in the second horizontal direction (the Y direction). For example, the distance between the plurality of first horizontal mask openings MKO-X in the second horizontal direction (the Y direction) may be about 250 nm.

Although FIGS. 2A to 2C illustrate that a horizontal width in the second horizontal direction (the Y direction) of the first horizontal mask opening MKO-X overlapping a tread of the semiconductor layer 110 at the bottom, from among the plurality of first horizontal mask openings MKO-X, is smaller than a horizontal width in the second horizontal direction of another first horizontal mask opening MKO-X, this is merely an example, and example embodiments are not limited thereto. For example, the plurality of first horizontal mask openings MKO-X may have an approximately same width in the second horizontal direction (the Y direction).

Referring to FIGS. 2A to 3C, the first insulating layer 200, the stacked sacrificial structure 105ST, and the stacked semiconductor structure 110ST are partially removed using the first mask layer MK1 as an etching mask to form a first opening STO1 penetrating through the first insulating layer 200, the stacked sacrificial structure 105ST, and the stacked semiconductor structure 110ST. After forming the first opening STO1, the first mask layer MK1 may be removed. The substrate 100 may be exposed to a bottom surface of the first opening STO1.

The first opening STO1 may include a plurality of first horizontal openings STO-X and second horizontal opening STO-Y communicating each other. The second horizontal opening STO-Y may have a planar shape of a line or bar extending in the second direction (the Y direction). Each of the plurality of first horizontal openings STO-X may have a planar shape of a line or bar crossing with the second horizontal opening STO-Y and extending in the first horizontal direction (the X direction).

The plurality of first horizontal openings STO-X may be apart from one another in the second horizontal direction (the Y direction) and cross with the second horizontal opening STO-Y. The number of the first horizontal openings STO-X may be greater than the number of the plurality of semiconductor layers 110. In some example embodiments, the second horizontal opening STO-Y may extend in the second horizontal direction (the Y direction) along centers in the first horizontal direction (the X direction) of the plurality of first horizontal openings STO-X.

The second horizontal opening STO-Y may extend in the second horizontal direction (the Y direction) between ends of the stacked sacrificial structure 105ST and the stacked semiconductor structure 110ST. The second horizontal opening STO-Y may separate the stacked sacrificial structure 105ST and the stacked semiconductor structure 110ST. That is, by one second horizontal opening STO-Y, the stacked sacrificial structure 105ST and the stacked semiconductor structure 110ST may be separated into two stack structures apart from each other in the first horizontal direction (the X direction).

Although FIG. 3A to 3C illustrate only one second horizontal opening STO-Y crossing between the stacked sacrificial structure 105ST and the stacked semiconductor structure 110ST, this is merely an example, and example embodiments are not limited thereto. For example, a plurality of second horizontal openings STO-Y apart from each other in the first horizontal direction (X) may cross between the stacked sacrificial structure 105ST and the stacked semiconductor structure 110ST. By the plurality of second horizontal openings STO-Y, the stacked sacrificial structure 105ST and the stacked semiconductor structure 110ST may be separated into stack structures, the number of which is one more than the number of the plurality of second horizontal openings STO-Y, and which is apart from each other in the first horizontal direction (the X direction).

A horizontal width of the first horizontal opening STO-X in the first horizontal direction (the X direction) may have a value greater than a value of the horizontal width of the second horizontal opening STO-Y in the first horizontal direction (the X direction). For example, the horizontal width of the first horizontal opening STO-X in the first horizontal direction (the X direction) may be about 750 nm, and the horizontal width of the second horizontal opening STO-Y in the first horizontal direction (the X direction) may be about 200 nm.

The horizontal width of the first horizontal opening STO-X in the second horizontal direction (the Y direction) may have a value less than a value of the horizontal width of the first horizontal opening STO-X in the first horizontal direction (the X direction). For example, the horizontal width of the first horizontal opening STO-X in the second horizontal direction (the Y direction) may be about 250 nm. In some example embodiments, the horizontal width of the first horizontal opening STO-X in the second horizontal direction (the Y direction) may have a value greater than a value of the horizontal width of the second horizontal opening STO-Y in the first horizontal direction (the X direction).

In some example embodiments, a distance between the plurality of first horizontal openings STO-X in the second horizontal direction (the Y direction) may have a value approximately identical to a value of the horizontal width of the first horizontal opening STO-X in the second horizontal direction (the Y direction). For example, the distance between the plurality of first horizontal openings STO-X in the second horizontal direction (the Y direction) may be about 250 nm.

Referring to FIGS. 3A to 4C, a plurality of first removal gaps 105G1 are formed by removing some of the plurality of sacrificial layers 105 exposed through the first opening STO1. In some example embodiments, the plurality of first removal gaps 105G1 may be formed by performing an isotropic etching process to remove a portion of the plurality of sacrificial layers 105 exposed through the first opening STO1. The plurality of first removal gaps 105G1 may be formed between the substrate 100 and a semiconductor layer 110 at the bottom of the plurality of semiconductor layers 110, between two semiconductor layers 110 adjacent to each other in the vertical direction, and a semiconductor layer 110 at top of the plurality of semiconductor layers 110 and the first insulting layer 200. The plurality of first removal gaps 105G1 may communicate with the first opening STO1.

Portions of the plurality of semiconductor layers 110, which are defined by the plurality of first removal gaps 105G1 and the first openings STO1, may be named as a plurality of semiconductor protrusions 110P. The plurality of semiconductor protrusions 110P may include portions of the plurality of semiconductor layers 110 protruding between the plurality of sacrificial layers 105.

Referring to FIGS. 4A to 5C, a portion of the plurality of semiconductor protrusions 110P exposed through the first opening STO1 and the plurality of first removal gaps 105G1 are removed to form the expanded gap 105GE by expansion of the first removal gap 105G1, and the plurality of semiconductor protrusion structures 110PS are formed by removing some of the plurality of semiconductor protrusions 110P.

As a result of removing a portion of the plurality of semiconductor protrusions 110P to form the expanded gap 105GE, a thickness in the vertical direction (the Z direction) of the plurality of semiconductor protrusion structures 110PS adjacent to the first opening STO1 may be smaller than a thickness in the vertical direction (the Z direction) of the plurality of semiconductor protrusion structures 110PS adjacent to the plurality of sacrificial layers 105. In some example embodiments, the thickness in the vertical direction (the Z direction) of the plurality of semiconductor protrusion structures 110PS may decrease from the plurality of sacrificial layers 105 toward the first opening STO1.

Referring to FIGS. 5A to 6C, a first insulating opening 200O is formed by removing a portion of the first insulating layer 200 such that the plurality of semiconductor protrusion structures 110PS and a portion of the stacked sacrificial structure 105ST adjacent to the plurality of semiconductor protrusion structures 110PS are exposed.

In some example embodiments, the first insulating opening 200O may have a planar shape, including a bar shape having a relatively great horizontal width and extending in the second horizontal direction (the Y direction) or a rectangular shape having a long axis in the second horizontal direction (the Y direction). In the vertical direction (the Z direction), in the first insulating opening 200O, the first opening STO1 and the plurality of semiconductor protrusion structures 110PS may all overlap. In the vertical direction (the Z direction), in the first insulating opening 200O, a portion of the stacked sacrificial structure 105ST and a portion of the stacked semiconductor structure 110ST, which are adjacent to the plurality of semiconductor protrusion structures 110PS, may overlap each other.

In some other example embodiments, the first insulating opening 200O may have a L-shaped planar shape to further expose a portion of the substrate 100 in which the stacked sacrificial structure 105ST and the stacked semiconductor structure 110ST are not arranged.

Referring to FIGS. 6A to 7C, a gate structure 120 is formed to cover a surface of a portion of the stacked sacrificial structure 105ST and a surface of the plurality of semiconductor protrusion structures 110PS, which are exposed without being covered by the first insulating layer 200, that is, exposed in the first insulating opening 200O. After forming the gate structure 120, the first insulating layer 200 may be removed.

The gate structure 120 may have a stack structure including a gate dielectric film 122 and a gate electrode film 124. For example, the gate structure 120 may be formed by forming the gate dielectric film 122 covering the surface of the portion of the stacked sacrificial structure 105ST and the surface of the plurality of semiconductor protrusion structures 110PS exposed in the first insulating opening 200O and then forming the gate electrode film 124 covering the gate dielectric film 122. The gate dielectric film 122 may conformally cover the surface of the portion of the stacked sacrificial structure 105ST and the surface of the plurality of semiconductor protrusion structures 110PS exposed in the first insulating opening 200O, and the gate electrode film 124 may conformally cover the gate dielectric film 122.

In some example embodiments, the gate structure 120 including the gate dielectric film 122 and the gate electrode film 124 may be arbitrarily formed on the surface of the stacked sacrificial structure 105ST and the surface of the plurality of semiconductor protrusion structures 110PS. In some other example embodiments, regarding the gate structure 120 including the gate dielectric film 122 and the gate electrode film 124, after being formed on all of a surface of the first insulating layer 200, the surface of the stacked sacrificial structure 105ST, and the surface of the plurality of semiconductor protrusion structures 110PS, the first insulating layer 200 and a portion of the gate structure 120 covering the surface of the first insulating layer 200 may be removed, and the gate structure 120 may remain only on the surface of the portion of the stacked sacrificial structure 105ST and the plurality of semiconductor protrusion structures 110PS exposed in the first insulating opening 200O.

The gate dielectric film 122 may include any one material selected from among silicon oxide, a high-k electric material having a dielectric constant higher than that of the silicon oxide, and a ferroelectric material. In some example embodiments, the gate dielectric film 122 may have a stack structure including a first dielectric film including silicon oxide, and a second dielectric film including any one material selected from among the high-k dielectric material and the ferroelectric material. For example, the high-k electric material and the ferroelectric material may include any one material selected from among hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barkum titanium oxide (BaTiO), lead zirconate titanate (PZT), strontium bismuth tantalate (STB), bismuth iron oxide (BFO), strontium titanum oxide (SrTiO), yittrium oxide (YO), aluminum oxide (AlO), or lead scandium tantalum oxide (PbScTaO).

In some example embodiments, the gate electrode film 124 may include a conductive barrier film covering the gate dielectric film 122 and a conductive charging layer covering the conductive barrier film. The conductive barrier film may include, for example, a metal, a conductive metal nitride, a conductive metal silicide, or combinations thereof. For example, the conductive barrier film may include TiN. The conductive charging layer may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or combinations thereof. In some example embodiments, the conductive charging layer may include W.

Referring to FIGS. 8A to 8D, the first opening STO1 and the expanded gap 105GE are filled with a second insulating layer 210 (covering the stacked sacrificial structure 105ST and the plurality of semiconductor protrusion structures 110PS), and then a second mask layer MK2 having the second mask opening MKO2 is formed on the second insulating layer 210.

For example, the second insulating layer 210 may include silicon oxide or an insulating material having a permittivity lower than a permittivity of silicon oxide. In some example embodiments, the second insulating layer 210 may include a tetraethyl orthosilicate (TEOS) film or an ultra-low K (ULK) film having an ultra-low dielectric constant K of from about 2.2 to about 2.4. The ULK may include a SiOC film or SiCOH film.

The second mask layer MK2 may overlap all of the first opening STO1, the expanded gap 105GE, and the plurality of semiconductor protrusion structures 110PS in the vertical direction (the Z direction). That is, the second mask opening MKO2 may not overlap the first opening STO1, the expanded gap 105GE, and the plurality of semiconductor protrusion structures 110PS in the vertical direction (the Z direction). The second mask layer MK2 may overlap, in the vertical direction (the Z direction), a portion of the stacked sacrificial structure 105ST and a portion of the stacked semiconductor structure 110ST adjacent to the plurality of semiconductor protrusion structures 110PS. That is, in a top-view, the second mask opening MKO2 may be apart from the first opening STO1, the expanded gap 105GE, and the plurality of semiconductor protrusion structures 110PS.

In some example embodiments, the second mask layers MK2 may overlap all of the gate structure 120 in the vertical direction (the Z direction). That is, the second mask opening MKO2 may not overlap the gate structure 120 in the vertical direction (the Z direction).

The second mask opening MKO2 may include a plurality of narrow mask openings MKO-N extending in the first horizontal direction (the X direction) and apart from one another in the second horizontal direction (the Y direction) and a wide mask opening MKO-W apart from the plurality of narrow mask openings MKO-N. The wide mask opening MKO-W and the plurality of narrow mask openings MKO-N may be apart from each other and sequentially arranged in the second direction (the Y direction).

The plurality of narrow mask openings MKO-N may overlap a sacrificial layer 105 at the top of the plurality of sacrificial layers 105 and the semiconductor layer 110 at the top of the plurality of semiconductor layers 110 in the vertical direction (the Z direction). The wide mask opening MKO-W may overlap a portion of the step shape of the stacked sacrificial structure 105ST and the stacked semiconductor structure 110ST in the vertical direction (the Z direction). The plurality of narrow mask openings MKO-N may have a planar shape including a bar shape extending in the first horizontal direction (the X direction) or a rectangular shape having a long axis in the first horizontal direction (the X direction). The wide mask opening MKO-W may have a planar shape including a rectangular shape or a square shape.

Referring to FIGS. 8A to 9D, a portion of each of the second insulating layer 210, the stacked sacrificial structure 105ST, and the stacked semiconductor structure 110ST are removed using the second mask layer MK2 as an etching mask to form the second opening STO2 penetrating the second insulating layer 210, the stacked sacrificial structure 105ST, and the stacked semiconductor structure 110ST. After the second opening STO2 is formed, the second mask layer MK2 may be removed. The substrate 100 may be exposed to a bottom surface of the second opening STO2.

The second opening STO2 may include a plurality of narrow openings STO-N extending in the first horizontal direction (the X direction) and apart from one another in the second horizontal direction (the Y direction) and a wide opening STO-W apart from the plurality of narrow openings STO-N. The wide opening STO-W and the plurality of narrow openings STO-N may be apart from each other and sequentially arranged in the second horizontal direction (the Y direction).

The plurality of narrow openings STO-N may have a planar shape including a bar shape extending in the first horizontal direction (the X direction) or a rectangular shape having a long axis in the first horizontal direction (the X direction). The wide opening STO-W may have a planar shape including a rectangular shape or a square shape.

Each of the plurality of semiconductor layers 110 may include a wide semiconductor structure 110W, a plurality of narrow semiconductor structures 110B, a connection semiconductor structures 110M, and the plurality of semiconductor protrusion structures 110PS. The plurality of narrow semiconductor structures 110B may include a portion of the semiconductor layer 110 arranged between the wide opening STO-W and the plurality of narrow openings STO-N. The plurality of narrow semiconductor structures 110B may connect the wide semiconductor structures 110W and the connection semiconductor structures 110M. That is, the plurality of narrow semiconductor structures 110B may have a bridge shape connecting the wide semiconductor structure 110W and the connection semiconductor structures 110M. The plurality of semiconductor protrusion structures 110PS may be connected to the connection semiconductor structures 110M. The connection semiconductor structures 110M may be between the plurality of semiconductor protrusion structures 110PS and the plurality of narrow semiconductor structures 110B. That is, with reference to the plurality of narrow semiconductor structures 110B, the connection semiconductor structures 110M may be arranged on side of the plurality of semiconductor protrusion structures 110PS, respectively, and the wide semiconductor structure 110W may be arranged opposite to the plurality of semiconductor protrusion structures 110PS. The plurality of narrow semiconductor structures 110B may have a planar shape including a bar shape extending in the first horizontal direction (the X direction) or a rectangular shape having a long axis in the first horizontal direction (the X direction). The wide semiconductor structure 110W, the plurality of narrow semiconductor structures 110B, the connection semiconductor structures 110M, and the plurality of semiconductor protrusion structures 110PS, which are included in each of the plurality of semiconductor layers 110, may be integral with one another.

Referring to FIGS. 9A to 10D, a plurality of second removal gaps 105G2 is formed by removing a portion of the plurality of sacrificial layers 105 through the second opening STO2. In some example embodiments, the plurality of second removal gaps 105G2 may be formed by removing a portion of the plurality of sacrificial layers 105 exposed through the second opening STO2 by performing an isotropic etching process.

The second removal gaps 105G2 may be formed between the narrow semiconductor structures 110B of the plurality of semiconductor layers 110, between the connection semiconductor structures 110M of the plurality of semiconductor layers 110, between the narrow semiconductor structure 110B of the semiconductor layer 110 at the bottom of the plurality of semiconductor layers 110 and the substrate 100, between a connection semiconductor structures 110M of the semiconductor layer at the bottom of the plurality of semiconductor layers 110 and the substrate 100, portions adjacent to the second opening STO2 between wide semiconductor structures 110W of the plurality of semiconductor layers 110, and a portion adjacent to the second opening STO2 between the substrate 100 and a wide semiconductor structure 110B of the semiconductor layer 110 at the bottom of the plurality of semiconductor layers 110. The plurality of second removal gaps 105G2 may communicate with the second opening STO2.

The connection semiconductor structures 110M of the plurality of semiconductor layers 110 may be apart from the plurality of sacrificial layers 105 without contact. The connection semiconductor structures 110M of the plurality of semiconductor layers 110 may be surrounded by the plurality of second removal gaps 105G2 and the second opening STO2.

Referring to FIGS. 10A to 11B, a portion of the gate structure 120 exposed through the plurality of second removal gap 105G2 is removed to split the gate structure 120 into a plurality of gate structures 120 respectively located at different vertical levels. The plurality of gate structures 120 split at the different vertical levels may cover the plurality of semiconductor layers 110 respectively located at the different vertical levels and may be apart from one another. The plurality of gate structures 120 that have been split may cover surfaces of the plurality of semiconductor protrusion structures 110PS, respectively, and cover a side surface of the connection semiconductor structure 110M facing the first opening STO1.

One of the plurality of gate structures 120 that have been split may include a first portion surrounding a corresponding one of the plurality of semiconductor protrusion structures 110PS included in a corresponding one of the plurality of semiconductor layers 110 and a second portion connecting the first portion surrounding each of the plurality of semiconductor protrusion structures 110PS included in a corresponding one of the plurality of semiconductor layers 110 and covering a side surface of each of the connection semiconductor structures 110M included in the corresponding one of the plurality of semiconductor layers 110. For example, the plurality of gate structures 120 may cover top surfaces and bottom surfaces of the plurality of semiconductor protrusion structures 110PS and side surfaces connecting the top surfaces and the bottom surfaces of the plurality of semiconductor protrusion structures 110PS.

Referring to FIGS. 11A to 12C, a second insulating opening 210O is formed by removing a portion of the second insulating layer 210. The second insulating opening 210O may overlap end portions of the plurality of semiconductor protrusion structures 110PS included in the semiconductor layer 110 at the top of the plurality of semiconductor layers 110. In other words, the end portions of the plurality of semiconductor protrusion structures 110PS face the second horizontal opening STO-Y in the vertical direction (Z direction). That is, portions of the gate structures 120 covering end portions of the semiconductor protrusion structure 110OS overlapping in the vertical direction (the Z direction) the plurality of semiconductor protrusion structures 110PS included in the semiconductor layer 110 at top of the plurality of semiconductor layers 110, from among the plurality of semiconductor protrusion structures 110PS included in the plurality of semiconductor layers 110, the end portions facing the second horizontal opening STO-Y, may be exposed. Portions of the gate structures 120, which cover the semiconductor protrusion structures 110PS and do not overlap in the vertical direction (the Z direction) the plurality of semiconductor protrusion structures 110PS included in the semiconductor layer 110 at the top of the semiconductor layers, 110 may be not exposed through the second insulating opening 210O.

Next, a portion of the gate structures 120 exposed inside the second insulating opening 210O is removed, such that end portions of the semiconductor protrusion structures 110PS overlapping in the vertical direction (the Z direction) with the plurality of semiconductor protrusion structures 110PS included in the semiconductor layer 110 at the top of the semiconductor layers 110, which face the second horizontal opening STO-Y, are exposed inside the second insulating opening 210O.

Referring to FIGS. 12A to 13B, a third insulating layer 220 is formed. In some example embodiments, after removing the second insulating layer 210, a third insulating layer 220 covering the stacked sacrificial structure 105ST and the stacked semiconductor structure 110ST may be formed on the substrate 100. In some other example embodiments, the second opening STO2 and an insulating material layer (not shown) filling the second opening STO2 may be formed such that the insulating material layer and the second opening STO2 together form the third insulating layer 220.

Referring to FIG. 13A to 14B, a portion of the third insulating layer 220 is removed to form a third insulating opening 2200 through which the wide semiconductor structure 110W is exposed, the plurality of sacrificial layers 105 are completely removed and the wide semiconductor structures 110W of the plurality of semiconductor layers 110 are removed, using the third insulating layer 220 as an etching mask, and then a third opening STO3 is formed. The substrate 100 may be exposed to a bottom surface of the third opening STO3, and the plurality of narrow semiconductor structures 110B may be exposed to an inner surface of the third opening STO3.

Referring to FIGS. 14A to 16C, the plurality of narrow semiconductor structures 110B are completely removed through the third opening STO3 to form a plurality of semiconductor openings 110O. In some example embodiments, portions of the connection semiconductor structures 110M may be exposed in the plurality of semiconductor openings 110O.

In some other example embodiments, in a process of forming the plurality of semiconductor openings 110O, the entire portions of the plurality of narrow semiconductor structures 110B and portions of the connection semiconductor structures 110M are removed, and by doing so, the plurality of semiconductor protrusion structures 110PS may be exposed in the plurality of semiconductor openings 110O.

Referring to FIGS. 16A and 16B, a lower electrode material layer (not shown) conformally covering surfaces exposed in the plurality of semiconductor openings 110O is formed. The lower electrode material layer may conformally cover a surface of the third insulating layer 220 and a surface of the connection semiconductor structure 110M exposed to the inside of the plurality of semiconductor openings 110O. Next, a portion of the lower electrode material layer outside the plurality of semiconductor openings 110O (e.g., in the third opening STO3) and a top surface of the third insulating layer 220, may be removed to form a plurality of lower electrode layers 310.

In some example embodiments, the plurality of lower electrode layers 310 may be formed into an empty cylinder shape in which a portion facing the third opening STO3 in the first horizontal direction (the X direction) is open and a portion facing the connection semiconductor structure 110M is closed. Each of the plurality of lower electrode layers 310 may contact a corresponding one of the connection semiconductor structures 110M.

In some other example embodiments, the plurality of lower electrode layers 310 may be formed in an empty cylinder shape in which the portion facing the third opening STO3 in the first horizontal direction (the X direction) is open and a portion facing the plurality of semiconductor protrusion structures 110PS is closed. Each of the lower electrode layers 310 may contact a corresponding one of the plurality of semiconductor protrusion structures 110PS.

Next, a capacitor dielectric film 320 conformally covering the plurality of lower electrode layers 310 and an upper electrode layer 330 covering the capacitor dielectric film 320 and filling the plurality of semiconductor openings 110O may be formed, and by doing so, a plurality of cell capacitors 300 each including a corresponding one of the plurality of lower electrode layers 310, a capacitor dielectric film 320, and a upper electrode layer 330 may be formed. In some example embodiments, the capacitor dielectric film 320 and the upper electrode layer 330 may each cover an inner surface of the third opening STO3.

The lower electrode layer 310 may include a metal, a conductive metal nitride, a conductive metal silicide, or combinations thereof. For example, the lower electrode layer 310 may include a refractory metal film including metal (e.g., cobalt, titanium, nickel, tungsten, or molybdenum). For example, the lower electrode layer 310 may include a metal nitride film (e.g., a titanium nitride film, a titanium silicon nitride film, a titanium aluminum nitride film, a tantalum nitride film, a tantalum silicon nitride film, a tantalum aluminum nitride film, or a tungsten nitride film).

The capacitor dielectric film 320 may include any one material selected from among a high-k dielectric material having a dielectric constant higher than that of the silicon oxide and a ferroelectric material. For example, the capacitor dielectric film 320 may include at least one of a metal oxide or a dielectric material having a perovskite structure. In some example embodiments, the capacitor dielectric film 320 may include any one material selected from among hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barkum titanium oxide (BaTiO), lead zirconate titanate (PZT), strontium bismuth tantalate (STB), bismuth iron oxide (BFO), strontium titanum oxide (SrTiO), yittrium oxide (YO), aluminum oxide (AlO), or lead scandium tantalum oxide (PbScTaO).

The upper electrode layer 330 may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or combinations thereof. In some example embodiments, the upper electrode layer 330 may include W.

Referring to FIGS. 16A to 17B, a portion of the connection semiconductor structures 110M is removed such that portions of the semiconductor layer 110 respectively connected to a plurality of the lower electrode layers 310 are apart from one another. In a process of removing a portion of the connection semiconductor structure 110M, some of the third insulating layer 220 may be removed together.

From among the portions of the semiconductor layer 110 respectively connected to the plurality of lower electrode layers 310, a portion having a horizontal width corresponding to a horizontal width of the plurality of semiconductor layers 110 in the second horizontal direction (the Y direction) may be named as a short connection semiconductor structure 110MS, and a portion having a relatively great horizontal width may be named as a long connection semiconductor structure 110ME. As the short connection semiconductor structure 110MS and the long connection semiconductor structure 110ME are each a portion of the connection semiconductor structures 110M, in description without distinction, both the short connection semiconductor structure 110MS and the long connection semiconductor structure 110ME may be named as the connection semiconductor structures 110M.

The semiconductor layers 110 at the top of the semiconductor layers 110 included in the stacked semiconductor structure 110ST may respectively include the short connection semiconductor structure 110MS and the semiconductor protrusion structure 110PS integral with the short connection semiconductor structure 110MS and connected thereto. From among the semiconductor layers 110 except the semiconductor layers 110 at the top of the semiconductor layers 110 from among the semiconductor layers 110 included in the stacked semiconductor structure 110ST, each of the semiconductor layers 110 connected to the lower electrode layers 310 at an edge in the second horizontal direction (the Y direction) from among the plurality of lower electrode layers 310 may include the long connection semiconductor structure 110ME and the semiconductor protrusion structure 110PS integral with the long connection semiconductor structure 110ME and connected thereto, and each of other semiconductor layers 110 may include the short connection semiconductor structure 110MS and the semiconductor protrusion structures 110PS integral with the short connection semiconductor structure 110MS and connected thereto.

That is, except the semiconductor layers 110 at the top of the semiconductor layers 110 from among the semiconductor layers 110 included in the stacked semiconductor structure 110ST, one of the semiconductor layers 110 at a same vertical level may include the long connection semiconductor structure 110ME and the semiconductor protrusion structure 110PS integral with the long connection semiconductor structure 110MS and connected thereto, and each of the other semiconductor layers 110 may include the short connection semiconductor structure 110MS and the semiconductor protrusion structure 110PS integral with the short connection semiconductor structure 110MS and connected thereto.

Next, a fourth insulating layer 230 is formed. In some example embodiments, after removing the third insulating layer 220, the fourth insulating layer 230 covering the stacked semiconductor structure 110ST may be formed on the substrate 100. In some other example embodiments, an insulating material layer (not shown) filling the third opening STO3 and a space from which a portion of the connection semiconductor structures 110M has been removed, such that the insulating material layer and the third insulating layer 230 together form the fourth insulating layer 230.

In some example embodiments, before forming the fourth insulating layer 230, a portion of the capacitor dielectric film 320 and a portion of the upper electrode layer 330, which cover a portion of an inner surface of the third opening STO3, may be removed. For example, a portion of the capacitor dielectric film 320 and a portion of the upper electrode layer 330, which cover a portion of the fourth insulating layer 230 apart from the plurality of semiconductor openings 110O in the inner surface of the third opening STO3, may be removed.

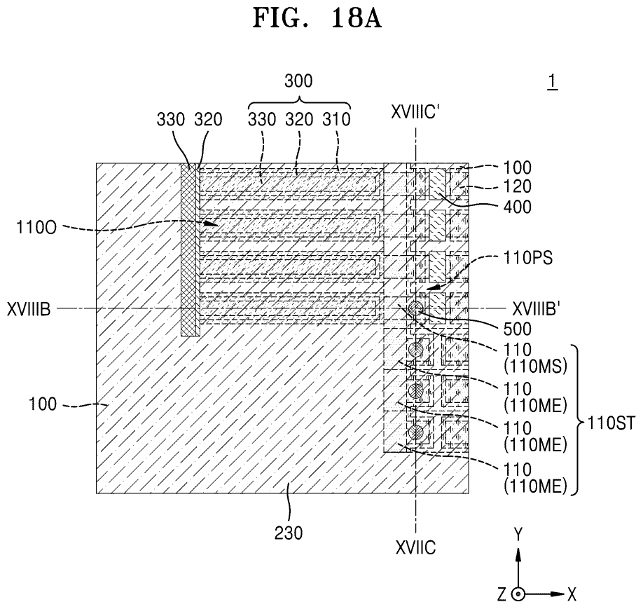

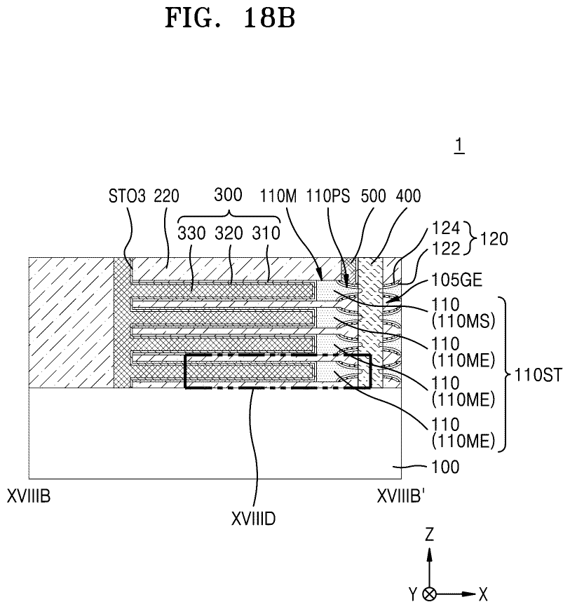

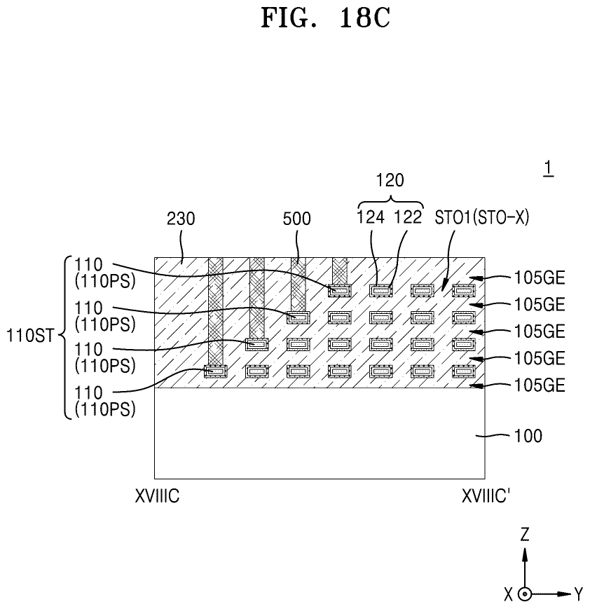

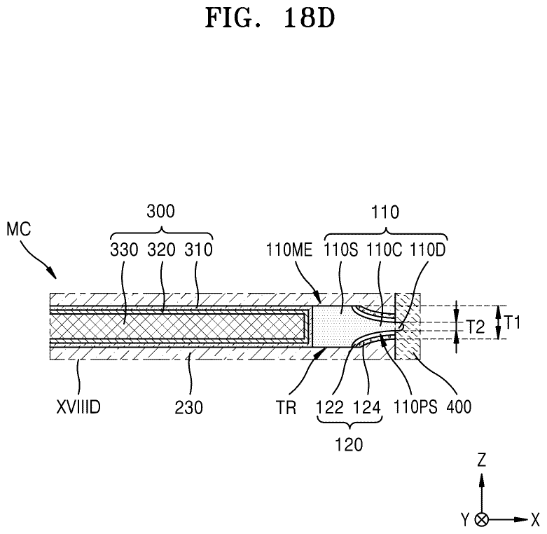

FIGS. 18A to 18D are diagrams of a semiconductor memory device 1 according to an example embodiment of the inventive concepts; More particularly, FIG. 18A is a top-plan view seen from top; and FIGS. 18B, 18C, and 18D are each a diagram of a cross-section taken along line XVIIIB-XVIIIB′ shown in FIG. 18A, line XVIIIC-XVIIIC′ shown in FIG. 18A, and line XVIIIC-XVIIIC′ shown in FIG. 18A. In addition, FIGS. 18A to 18D are top-plan views and cross-sectional views of portion EX shown in FIG. 1A.

Referring to FIGS. 18A to 18D, the semiconductor memory device 1 is formed by forming a plurality of bit lines 400 and a plurality of word line contacts 500.

The plurality of bit lines 400 may respectively penetrate through the fourth insulating layer 230 and be connected to the end portions of the semiconductor protrusion structures 110PS. In some example embodiments, the plurality of bit lines 400 may contact the substrate 100. The plurality of bit lines 400 may be connected to end portions of the plurality of semiconductor protrusion structures 110PS that are not covered by the gate structure 120. The plurality of bit lines 400 may extend in the vertical direction (the Z direction) and be arranged apart from one another in the second horizontal direction (the Y direction).

In some example embodiments, each of the plurality of bit lines 400 may include a conductive barrier film contacting the semiconductor protrusion structure 110PS and a conductive charging layer covering the conductive barrier film. The conductive barrier film may include, for example, a metal, a conductive metal nitride, a conductive metal silicide, or combinations thereof. For example, the conductive barrier film may include TiN. The conductive charging layer may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or combinations thereof. In some example embodiments, the conductive charging layer may include W.

The semiconductor protrusion structures 110PS may be respectively connected to two side surfaces of each of the plurality of bit lines 400. For example, the semiconductor protrusion structures 110PS may be respectively connected to two sides in the first horizontal direction (the X direction) of the bit line 400. The semiconductor protrusion structures 110PS arranged apart from one another in the vertical direction (the Z direction) may be connected to a side surface of the bit line 400. The semiconductor protrusion structures 110PS connected to the two side surfaces of the plurality of bit lines 400 may be arranged in a mirror symmetry with reference to a straight line, which extends in the second horizontal direction (the Y direction) along the plurality of bit lines 400, or a Y-Z plane.

The plurality of word line contacts 500 may penetrate through the fourth insulating layer 230 and may be connected to the plurality of gate structures 120 respectively located at different vertical levels. The plurality of word line contacts 500 may be apart from the plurality of bit lines 400 in the first horizontal direction (the X direction). A portion of the fourth insulating layer 230 may fill a gap between the word line contact 500 and the bit line 400 adjacent to each other in the first horizontal direction (the X direction). The plurality of word line contacts 500 may be connected a portion of a corresponding one of the plurality of gate structures 120 surrounding the semiconductor protrusion structure 110PS. The plurality of word line contacts 500 may be connected to a portion of the gate structure 120 surrounding a corresponding one of the plurality of semiconductor protrusion structures 110PS located at a same vertical level. For example, a bottom surface of each of the plurality of word line contacts 500 may contact a portion of the gate electrode film 124 of the gate structure 120 covering a top surface of the semiconductor protrusion structure 110PS. The plurality of word line contacts 500 may be arranged apart from one another in the second horizontal direction (the Y direction). The plurality of word line contacts 500 arranged apart from one another in the second horizontal direction (the Y direction) and connected to the plurality of gate structures 120 respectively located at different levels may respectively have different heights (e.g., different lengths of extension in the vertical direction (the Z direction)).

Each of the semiconductor layers 110 may include a source area 110S, a channel area 110C, and a drain area 110D. In some example embodiments, the source area 110S may include the connection semiconductor structure 110M of the semiconductor layer 110, that is, the short connection semiconductor structure 110MS or the long connection semiconductor structure 110ME. In some other example embodiments, the source area 110S may include a portion of the connection semiconductor structure 110M adjacent to the semiconductor protrusion structure 110PS, that is, a portion of the short connection semiconductor structure 110MS or a portion of the long connection semiconductor structure 110ME. In some other example embodiments, the source area 110S may include a portion of the semiconductor protrusion structure 110PS adjacent to the connection semiconductor structure 110M (e.g., the short connection semiconductor structure 110MS or the long connection semiconductor structure 110ME). The channel area 110C may include a portion of the semiconductor protrusion structure 110PS surrounded by the gate structure 120 (e.g., a portion covered by the gate dielectric film 122), and the drain area 110D may include a portion of the semiconductor protrusion structure 110PS not surrounded by the gate structure 120 (e.g., a portion not covered by the gate dielectric film 122). The gate structure 120 may extend covering a top surface and a bottom surface of the channel area 110C and two side surfaces of the channel area 110C that connect the top surface and the bottom surface. Thus, the gate structure 120 may surround the channel area 110C.

The channel area 110C may include impurities of a first conductive type, and the source area 110S and the drain area 110D may include impurities of a second conductive type different from the impurities of the first conductive type. In some example embodiments, the first conductive type may indicate p type, and the second conductive type may indicate n type. The source area 110S and the drain area 110D may each be formed by injecting impurities to a portion of the semiconductor layer 110 or by removing a portion of the semiconductor layer 110 and then growing a semiconductor layer including impurities of the second conductive type. In some example embodiments, the source area 110S and the drain area 110D may each be formed by performing a gas phase diffusion process or an epitaxial growth process on a portion of the semiconductor layer 110.

The semiconductor layer 110 and a portion of the gate structure 120 surrounding the channel area 110C of the semiconductor layer 110 may form a cell transistor TR. The cell transistor TR and the cell capacitor 300 may form a memory cell MC. The cell capacitor 300 may be connected to the source area 110S of the semiconductor layer 110. For example, the lower electrode layer 310 may be connected to the source area 110S of the semiconductor layer 110. The bit line 400 may be connected to the drain area 110D of the semiconductor layer 110. The cell capacitor 300, the cell transistor TR, and the bit line 400 may be sequentially aligned in the first horizontal direction (the X direction). The gate structure 120 may approximately extend in the second horizontal direction (the Y direction). The bit line 400 may extend in the vertical direction (the Z direction).

The semiconductor memory device 1 may include a plurality of the memory cells MC apart from one another in the second horizontal direction (the Y direction) and the vertical direction (Z direction) and arranged in columns and rows, the plurality of bit lines 400 extending in the vertical direction (the Z direction) and connected to the cell transistors TR of the memory cells MC arranged in the vertical direction (the Z direction), the plurality of bit lines 400 arranged apart from one another in the second horizontal direction (the Y direction), and the plurality of word line contacts 500 extending in the vertical direction (the Z direction) and arranged apart from one another in the second horizontal direction (the Y direction). On the substrate 100, the fourth insulating layer 230 may cover the plurality of semiconductor layers 110, the plurality of gate structures 120, the cell capacitor 300, the plurality of bit lines 400, and the plurality of word line contacts 500.

Each of the plurality of memory cells MC may include the cell transistor TR and the cell capacitor 300. The cell transistor TR and the cell capacitor 300 included in each of the plurality of memory cells MC may be arranged in the first horizontal direction (the X direction). The cell transistor TR may include the semiconductor layer 110 including the source area 110S, the channel area 110C, and the drain area 110D, the gate dielectric film 122 surrounding the channel area 110C of the semiconductor layer 110, and the gate electrode film 124 on the gate dielectric film 122.

A thickness in the vertical direction (the Z direction) of an end of the semiconductor protrusion structure 110PS facing the cell capacitor 300 may be greater than a thickness in the vertical direction (the Z direction) of another end of the semiconductor protrusion structure 110PS facing the bit line 400. For example, a first thickness T1 in the vertical direction (the Z direction) of an end of the channel area 110C facing the source area 110S may be greater than a second thickness T2 in the vertical direction (the Z direction) of the other end of the channel area 110C facing the drain area 110D. The first thickness T1 may be from about 20 nm to about 50 nm, and the second thickness T2 may be from about 5 nm to about 20 nm. A thickness in the vertical direction (the Z direction) of the source area 110S may be approximately equal to the first thickness, and a thickness in the vertical direction (the Z direction) of the drain area 110D may be equal to or less than the second thickness T2. A thickness of each of the plurality of semiconductor protrusion structures 110PS in the vertical direction (the Z direction) may decrease from the cell capacitor 300 toward the bit line 400. For example, a thickness in the vertical direction (the Z direction) of the channel area 110C may decrease from the source area 110S toward the drain area 110D.

The plurality of word line contacts 500 may be connected to the gate electrode films 124 of the plurality of gate structures 120. The plurality of bit lines 400 may be connected to the drain areas 110D of a plurality of the cell transistors TR. The plurality of cell capacitors 300 may include the plurality of lower electrode layers 310, the capacitor dielectric films 320, and the upper electrode layers 330. The plurality of lower electrode layers 310 may be connected to the source areas 110S of the plurality of cell transistors TR. In some example embodiments, the capacitor dielectric film 320 and the upper electrode layer 330 may sequentially cover the plurality of lower electrode layers 310, and may have a plate shape in which a portion extends in the second horizontal direction (the Y direction) and the vertical direction (the Z direction).

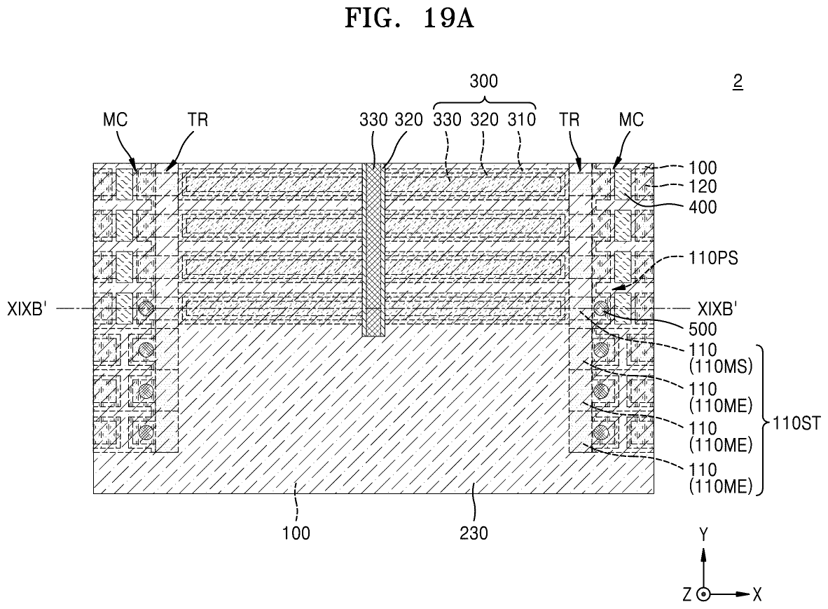

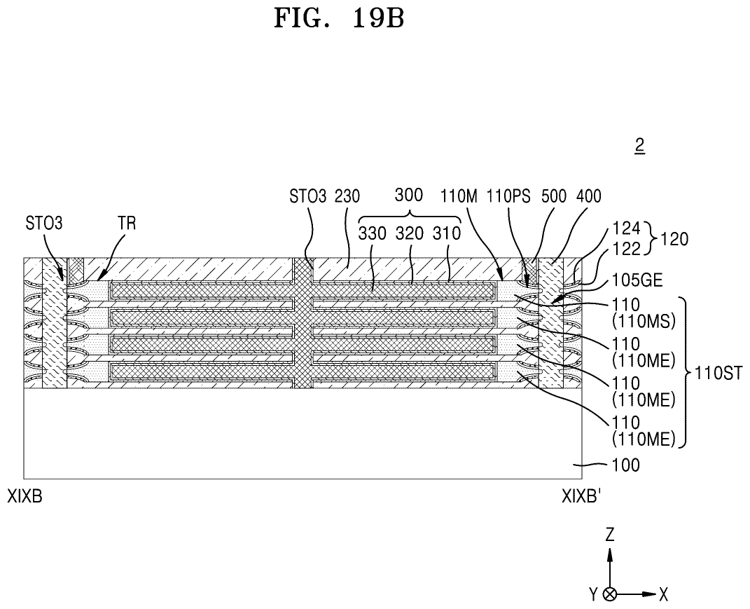

FIGS. 19A to 19B are diagrams of a semiconductor memory device 2 according to an example embodiment of the inventive concepts. More particularly, FIG. 19A is a top-plan view seen from top, and FIG. 19B is a diagram of a cross-section taken along line XIXB-XIXB′ shown in FIG. 19A. In FIGS. 19A and 19B, same contents as those in FIGS. 18A to 18D may be omitted.

Referring to FIGS. 19A and 19B, the semiconductor memory device 2 may include a plurality of memory cells arranged in a mirror symmetry in the first horizontal direction (the X direction) with reference to the upper electrode layer 330. In addition, the memory cells MC may be arranged in a mirror symmetry in the first horizontal direction (the X direction) with reference to the bit line 400.

That is, the semiconductor memory device 2 may include the plurality of memory cells MC arranged apart from one another in the second horizontal direction (the Y direction) and the vertical direction (the Z direction) and arranged in columns and rows, and the plurality of memory cells MC may be alternately arranged in a mirror symmetry with reference to the upper electrode layer 330 and the bit line 400 in the first horizontal direction (the X direction) to construct a memory cell array.

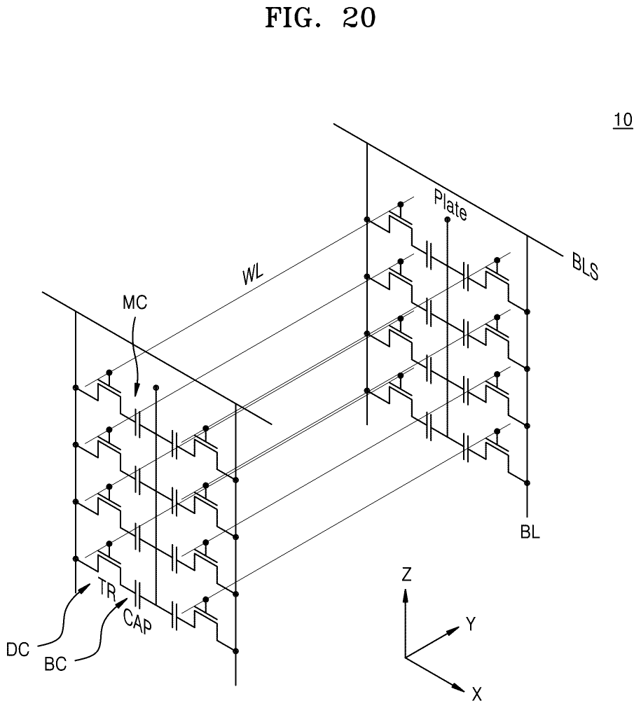

FIG. 20 is an equivalent circuit diagram of a memory cell array of a semiconductor memory device 10 according to an example embodiment of the inventive concepts.

Referring to FIG. 20, the semiconductor memory device 10 may include a plurality of memory cells MC including the cell transistors TR and cell capacitors CAP arranged in the first horizontal direction (the X direction) and connected to each other. The cell capacitor CAP may indicate the cell capacitor 300 shown in FIGS. 18A to 19B. The plurality of memory cells MC may be apart from one another in the second horizontal direction (the Y direction) and the vertical direction (the Z direction) and arranged in columns and rows.

A plurality of word lines WL extend in the second horizontal direction (the Y direction), and may be arranged apart from one another in the first horizontal direction (the X direction) and the vertical direction the Z direction. A word line WL may indicate the gate electrode film 124 shown in FIGS. 18A to 19B. A plurality of bit lines BL may extend in the vertical direction (the Z direction) and may be arranged apart from one another in the first horizontal direction (the X direction) and the second horizontal direction (the Y direction). A bit line BL may indicate the bit line 400 shown in FIGS. 18A to 19B.

In some example embodiments, some of the plurality of bit lines BL may be connected to each other by a bit line strapping line BLS extending in the first horizontal direction (the X direction). For example, the bit line strapping line BLS may connect bit lines BL aligned in the first horizontal direction (the X direction) from among the plurality of bit lines BL.

The plurality of cell capacitors CAP may be commonly connected to an upper electrode PLATE extending in the second horizontal direction (the Y direction) and the vertical direction (the Z direction). The upper electrode PLATE may indicate the upper electrode layer 330 shown in FIGS. 18A to 19B. For convenience of illustration, FIG. 20 illustrates that the upper electrodes PLATE are aligned or arranged in the second horizontal direction (the Y direction) and each of the upper electrodes PLATE extends in the vertical direction (the Z direction). However, the upper electrodes PLATES aligned or arranged in the second horizontal direction (the Y direction) may be integral with one another. The plurality of memory cells MC may be arranged in a mirror symmetry in the first horizontal direction (the X direction) with reference to the upper electrode PLATE.

The plurality of memory cells MC may be arranged in a mirror symmetry with reference to a surface extending in the second horizontal direction (the Y direction) and the vertical direction (the Z direction), the surface in which the upper electrode PLATE is arranged. In addition, as shown in FIGS. 19A and 19B, the plurality of memory cells MC may be arranged to be mirror symmetric with reference to a surface which extends in the second horizontal direction (the Y direction) and the vertical direction (the Z direction) and in which the bit lines BL are aligned in the second horizontal direction (the Y direction). The cell capacitors CAP and the cell transistors TR aligned in the first horizontal direction (the X direction) may be arranged to be mirror symmetric with reference to a surface which extends in the second horizontal direction (the Y direction) and the vertical direction (the Z direction) and in which the upper electrodes PLATE are arranged. In addition, the cell capacitors CAP and the cell transistors TR aligned in the first horizontal direction (the X direction) may be arranged to be mirror symmetric with reference to a surface which extends in the second horizontal direction and the vertical direction (the Z direction) and in which the bit lines BL are aligned or arranged in the second horizontal direction (the Y direction), as shown in FIGS. 19A and 19B.

The cell transistor may be connected to the bit line BL through DC and may be connected to the cell capacitor CAP through BC. The BC may correspond to the source area 110S shown in FIG. 18D. The DC may correspond to the drain area 110D shown in FIG. 18D.

The semiconductor memory device 10 may indicate the semiconductor memory device 1 shown in FIGS. 18A to 18D or the semiconductor memory device 2 shown in FIGS. 19A and 19B.

Referring to FIGS. 1A to 20, the semiconductor memory devices 1, 2, and 10 according to some example embodiments of the inventive concepts include the plurality of memory cells MC arranged apart one another in the second horizontal direction (the Y direction) and the vertical direction (the Z direction) and arranged in columns and rows, and the plurality of memory cells MC may be alternately arranged in a mirror symmetry in the first horizontal direction (the X direction), and thus the integrity of the semiconductor memory devices 1, 2, and 10 may be improved.

In addition, even when an element (e.g., Ge) included in the sacrificial layer 105 is diffused to a portion of the semiconductor layer 110, the semiconductor protrusion structure 110PS including the channel area 110C is formed by removing a portion of the semiconductor layer 110 contacting the sacrificial layer 105, and accordingly operation properties of the cell transistor TR including the channel area 110C may be improved.

In addition, as the semiconductor protrusion structure 110PS is formed by removing a portion of the semiconductor layer 110, the expanded gap 105GE (e.g., a gap between two semiconductor protrusion structures 110PS adjacent to each other) may increase in size. Accordingly, as the gate electrode film 124 surrounding the semiconductor protrusion structure 110PS may be formed in a relatively great thickness, a resistance of the gate electrode film 124 may be reduced.

While the inventive concepts have been particularly shown and described with reference to some example embodiments thereof, it will be understood that various changes in form and details may be made therein without departing from the spirit and scope of the following claims.

What is claimed is:

1. A semiconductor memory device comprising:
a semiconductor layer comprising a source area, a channel area, and a drain area arranged in a first horizontal direction on a substrate;
a cell capacitor extending in the first horizontal direction on the substrate and comprising a lower electrode layer, a capacitor dielectric film, and an upper electrode layer connected to the source area;
a bit line extending in a vertical direction on the substrate and connected to the drain area; and
a gate structure covering the channel area, the gate structure comprising a gate dielectric film on the channel area and a gate electrode film on the gate dielectric film,
wherein in the vertical direction, a first thickness of an end of the channel area facing the source area is greater than a second thickness of another end of the channel area facing the drain area.

2. The semiconductor memory device of claim 1, wherein a thickness of the channel area decreases from the source area toward the drain area.

3. The semiconductor memory device of claim 1, wherein a thickness of the source area in the vertical direction is the first thickness.

4. The semiconductor memory device of claim 1, wherein a thickness of the drain area in the vertical direction is less than or equal to the second thickness.

5. The semiconductor memory device of claim 1, further comprising:
a word line contact connected to the gate structure and extending in the vertical direction.

6. The semiconductor memory device of claim 5, wherein a bottom surface of the word line contact contacts a portion of the gate electrode film covering a top surface of the channel area.

7. The semiconductor memory device of claim 1, wherein
the semiconductor layer and the cell capacitor are arranged in the first horizontal direction, and
the semiconductor layer and the gate structure constitute a cell transistor.

8. The semiconductor memory device of claim 7, wherein
the cell transistor comprises a plurality of cell transistors apart from one another in a second horizontal direction orthogonal to the first horizontal direction and in the vertical direction, and
the plurality of cell transistors are arranged in columns and rows.

9. The semiconductor memory device of claim 8, wherein
the bit line comprises a plurality of bit lines arranged apart from one another in the second horizontal direction, and
a respective one of the plurality of bit lines is connected to the drain areas of a first group of cell transistors, the drain areas of the first group of cell transistors arranged apart from one another in the vertical direction.

10. The semiconductor memory device of claim 8, wherein
the gate structure comprises a plurality of gate structures arranged apart from one another in the vertical direction, and
the plurality of gate structures each cover the channel area of a corresponding one of a second group of cell transistors, the second group of cell transistors arranged apart from one another in the second horizontal direction and extend in the second horizontal direction.

11. A semiconductor memory device comprising:
a plurality of semiconductor layers each comprising a source area, a channel area, and a drain area arranged in a first horizontal direction on a substrate, the plurality of semiconductor layers being apart from one another in a second horizontal direction orthogonal to the first horizontal direction and in a vertical direction, the plurality of semiconductor layers arranged in columns and rows;
a plurality of cell capacitors extending in the first horizontal direction from the plurality of semiconductor layers, the plurality of cell capacitors comprising a plurality of lower electrode layers connected to source areas of the plurality of semiconductor layers, a capacitor electrode film covering the plurality of lower electrode layers, and an upper electrode film covering the capacitor electrode film;
a plurality of bit lines extending in the vertical direction on the substrate, the plurality of bit lines arranged apart from one another in the second horizontal direction, the plurality of bit lines each connected to the drain area of a corresponding one of the plurality of semiconductor layers; and
a plurality of gate structures covering the channel areas of the plurality of semiconductor layers and extending in the second horizontal direction, the plurality of gate structures each comprising a gate dielectric film on the channel area and a gate electrode film on the gate dielectric film,
wherein a thickness of the channel area in the vertical direction decreases from the source area toward the drain area.

12. The semiconductor memory device of claim 11, further comprising:
a plurality of word line contacts extending in the vertical direction, the plurality of word line contacts connected to the plurality of gate structures and arranged apart from one another in the second horizontal direction.

13. The semiconductor memory device of claim 12, wherein the plurality of word line contacts are connected to a group of gate structures, from among the plurality of gate structures, located at different vertical levels, respectively.

14. The semiconductor memory device of claim 13, wherein the plurality of word line contacts have different extension lengths in the vertical direction.

15. The semiconductor memory device of claim 12, wherein each of the plurality of gate structures surrounds the channel area by covering a top surface and a bottom surface of the channel area of a corresponding one of the plurality of semiconductor layers and two side surfaces of the channel area of the corresponding one of the plurality of semiconductor layers connecting the top surface and the bottom surface.

16. The semiconductor memory device of claim 15, wherein a bottom surface of each of the plurality of word line contacts contacts a portion of the gate electrode film covering a top surface of the channel area of a corresponding one of the plurality of semiconductor layers.

17. The semiconductor memory device of claim 11, wherein
one of the plurality of semiconductor layers and a corresponding one of the plurality of cell capacitors are arranged in the first horizontal direction,
the plurality of semiconductor layers constitute a plurality of cell transistors with corresponding ones of the plurality of gate structures, and
the plurality of cell transistors are arranged to be mirror symmetric in the first horizontal direction.

18. A semiconductor memory device comprising:
a plurality of semiconductor layers each comprising a source area, a channel area, and a drain area arranged in a first horizontal direction on a substrate, the plurality of semiconductor layers being apart from one another in a second horizontal direction orthogonal to the first horizontal direction and in a vertical direction, the plurality of semiconductor layers arranged in columns and rows;
a plurality of cell capacitors extending in the first horizontal direction from the plurality of semiconductor layers, the plurality of cell capacitors comprising a plurality of lower electrode layers connected to source areas of the plurality of semiconductor layers, a capacitor dielectric film covering the plurality of lower electrode layers, and an upper electrode film covering the capacitor dielectric film;
a plurality of bit lines extending in the vertical direction on the substrate, the plurality of bit lines each connected to the drain area of each of a group of semiconductor layers, which are arranged apart from one another in the vertical direction from among the plurality of semiconductor layers, the plurality of bit lines arranged apart from one another in the second horizontal direction;
a plurality of gate structures extending in the second horizontal direction, the plurality of gate structures surrounding the channel area of each of a group of semiconductor layers arranged apart from one another in the second horizontal direction from among the plurality of semiconductor layers, the plurality of gate structures each including a gate dielectric film on the channel area and a gate electrode film on the gate dielectric film;
a plurality of word line contacts extending in the vertical direction, the plurality of word line contacts arranged apart from one another in the second horizontal direction, the plurality of word line contacts being apart from the plurality of bit lines in the first horizontal direction, each of the plurality of word line contacts connected to the gate electrode film of a corresponding one of the plurality of gate structures; and
an insulating layer covering the plurality of semiconductor layers, the plurality of gate structures, the plurality of cell capacitors, the plurality of bit lines, and the plurality of word line contacts, on the substrate, the insulating layer filling a space between one of the plurality of bit lines and a corresponding one of the plurality of word line contacts, which is adjacent to the one of the plurality of bit lines in the first horizontal direction.

19. The semiconductor memory device of claim 18, wherein the upper electrode film covers the capacitor dielectric film covering the plurality of lower electrode layers and has a plate shape portion extending in the second horizontal direction and the vertical direction.

20. The semiconductor memory device of claim 18, wherein in the vertical direction,
a first thickness of an end of the channel area facing the source area is from 20 nm to 50 nm, and
a second thickness of another end of the channel area facing the drain area is less than the first thickness and is from 5 nm to 20 nm.
